(19) United States
(12) Patent Application Publication
(10) Pub. No.: US 2023/0091905 A1
(43) Pub. Date: Mar. 23, 2023

(54) ACOUSTIC DEVICE AND METHOD FOR MANUFACTURING THE SAME

(71) Applicant: WUHAN YANXI MICRO COMPONENTS CO., LTD., Wuhan (CN)

(72) Inventors: Yuxuan DONG, Wuhan (CN); Pei-chun LIAO, Wuhan (CN); Re-ching LIN, Wuhan (CN)

(73) Assignee: WUHAN YANXI MICRO COMPONENTS CO., LTD., Wuhan (CN)

(21) Appl. No.: 18/058,271

(22) Filed: Nov. 23, 2022

Related U.S. Application Data
(63) Continuation-in-part of application No. 16/544,984, filed on Aug. 20, 2019, now Pat. No. 11,539,340.
Application No. 16/544,984 is a continuation of application No. PCT/CN2018/125238, filed on Dec. 29, 2018.

(30) Foreign Application Priority Data
Jan. 19, 2018 (CN) 201810051954.3
Jan. 19, 2018 (CN) 201820096098.9
Feb. 5, 2018 (CN) 201810113583.7
Feb. 5, 2018 (CN) 201820198355.X

(51) Int. Cl. H03H 9/205; H03H 9/13; H03H 9/02; H03H 3/02

(52) U.S. Cl. CPC H03H 9/205; H03H 9/13; H03H 9/02157; H03H 3/02

(57) ABSTRACT

An acoustic device includes a plurality of bulk acoustic resonance structures. Each of the bulk acoustic resonance structures includes a substrate. The bulk acoustic resonance structure further includes a reflective structure, a first electrode layer, a piezoelectric layer and a second electrode layer stacked on the substrate in sequence. The bulk acoustic resonance structure further includes multiple protruding blocks located on the piezoelectric layer and circumferentially arranged around the second electrode layer, wherein the multiple protruding blocks have a preset distance from the second electrode layer, and the preset distance depends on a connection manner between the bulk acoustic resonance structure and other ones of multiple bulk acoustic resonance structures.

### CROSS-REFERENCE TO RELATED APPLICATIONS

This is a continuation-in-part application of U.S. patent application Ser. No. 16/544,984 filed on Aug. 20, 2019, which is a continuation of International Patent Application No. PCT/CN2018/125238 filed on Dec. 29, 2018, which claims priority to Chinese Patent Application No. 201810051954.3 filed on Jan. 19, 2018, Chinese Patent Application No. 201820096098.9 filed on Jan. 19, 2018, Chinese Patent Application No. 201810113583.7 filed on Feb. 5, 2018, and Chinese Patent Application No. 201820198355.X filed on Feb. 5, 2018. The disclosures of the above-referenced applications are hereby incorporated by reference in their entirety.

### BACKGROUND

In widely used communication devices such as mobile phones, acoustic devices using acoustic wave are generally used as filters of the communication devices. Devices using Bulk Acoustic Wave (BAW) are examples of the acoustic devices. Performance of the acoustic devices affects communication effect of the communication devices.

With development of communication technology, improving performance of the acoustic devices becomes an urgent problem to be solved.

### SUMMARY

Embodiment of the present disclosure relates to the technical field of semiconductor, and in particular to an acoustic device and a method for manufacturing the same.

In view of this, embodiments of the present disclosure provide an acoustic device and a method for manufacturing the same.

A first aspect of the embodiments of the present disclosure provides an acoustic device including multiple bulk acoustic resonance structures. Each of the multiple bulk acoustic resonance structures includes a substrate; a reflective structure, a first electrode layer, a piezoelectric layer and a second electrode layer stacked on the substrate in sequence; and multiple protruding blocks located on the piezoelectric layer and circumferentially arranged around the second electrode layer. Herein the multiple protruding blocks have a preset distance from the second electrode layer, and the preset distance depends on a connection manner between the bulk acoustic resonance structure and other ones of the multiple bulk acoustic resonance structures.

In the above scheme, in a case that the bulk acoustic resonance structure is connected to a branch of the acoustic device in series, the preset distance is less than or equal to a first distance. In a case that the bulk acoustic resonance structure is connected to the branch of the acoustic device in parallel, the preset distance is greater than the first distance.

In the above scheme, the first distance is greater than or equal to zero and is less than a spacing between an outer contour of the piezoelectric layer and an outer contour of the second electrode layer.

In the above scheme, the first distance is 4 μm.

In the above scheme, distances between the multiple protruding blocks and the second electrode layer are the same or different.

In the above scheme, each of the multiple protruding blocks has a size of 0.5 μm to 4 μm in a first direction, a size of 10 μm to 40 μm in a second direction, and a size of 0.1 μm to 1 μm in a third direction. Herein the first direction is a direction from an edge of the second electrode layer to a middle of the second electrode layer. The second direction is perpendicular to the first direction and parallel to a surface of the substrate. The third direction is perpendicular to the surface of the substrate.

In the above scheme, the each of the multiple protruding blocks has a size of 2 μm in in the first direction, a size of 10 μm in the second direction and a size of 0.5 μm in the third direction

In the above scheme, an outer contour of the second electrode layer is of a closed shape including a curve and two or more straight lines.

In the above scheme, the closed shape includes the curve and the two straight lines of a same length, and the two straight lines form an angle of 0 degree to 180 degrees. A maximum distance between the curve and an intersection of the two straight lines is L1, and each of the two straight lines has a length of L2. Herein a ratio of L2 to (L1−L2) ranges from 1:0.1 to 1:6.

In the above schemes, the ratio of L2 to (L1−L2) is 1:3, and the two straight lines form an angle of 45 degrees to 135 degrees.

In the above schemes, the closed shape includes the curve, a first straight line, a second straight line and a third straight line. The first straight line is connected to one end of the curve and one end of the third straight line, and the second straight line is connected to another end of the curve and another end of the third straight line. The first straight line and the third straight line form an angle of 90 degrees, and the second straight line and the third straight line form an angle of 90 degrees. A maximum distance between the curve and the third straight line is L3. Each of first straight line and the second straight line has a length of L4, and a ratio of (L3−L4) to L4 ranges from 0.36:1 to 4.5:1.

In the above schemes, the bulk acoustic resonance structure further includes a first electrode lead, a first conductive thickening layer, a second electrode lead and a second conductive thickening layer. The first electrode lead is connected to the first electrode layer and is located outside an active area. The first conductive thickening layer is located between the first electrode lead and the piezoelectric layer. The second electrode lead is connected to the second electrode layer and is located outside the active area. The second conductive thickening layer covers the second electrode lead.

In the above schemes, the first conductive thickening layer has a same shape as that of the first electrode lead, and/or the second conductive thickening layer has a same shape as that of the second electrode lead.

In the above schemes, a material of the first conductive thickening layer is the same as or different from a material of the first electrode lead, and/or a material of the second conductive thickening layer is the same as or different from a material of the second electrode lead.

A second aspect of the embodiments of the present disclosure provides a method for manufacturing an acoustic device. The acoustic device includes multiple bulk acoustic resonance structures, and the method includes that each of the multiple bulk acoustic resonance structures is formed, which includes the following operations. A reflective structure is formed on a substrate. A first electrode layer is formed on the reflective structure. A piezoelectric layer is formed on the first electrode layer. A second electrode layer is formed on the piezoelectric layer. Multiple protruding blocks are formed on the piezoelectric layer. Herein the multiple protruding blocks are circumferentially arranged around the second electrode layer. The multiple protruding blocks have a preset distance from the second electrode layer, and the preset distance depends on a connection manner between the each bulk acoustic resonance structure and other ones of the multiple bulk acoustic resonance structures.

In the above schemes, the operation of forming the multiple protruding blocks includes the following operations. A first material layer covering part of the piezoelectric layer is formed. Herein the first material layer is in contact with the second electrode layer. Multiple first mask layers covering parts of the first material layer are formed, where the multiple first mask layers are circumferentially arranged around the second electrode layer. Remaining parts of the first material layer not covered by the multiple first mask layers are removed, and a distance between the piezoelectric layer and each of the parts of the first material layer covered by a respective one of the multiple first mask layers are adjusted to obtain the multiple protruding blocks.

Alternatively, the operation of forming the multiple protruding blocks includes the following operations. A second material layer covering part of the piezoelectric layer and the second electrode layer is formed. Multiple second mask layers covering parts of the second material layer are formed, where the multiple second mask layers are circumferentially arranged around the second electrode layer and have the preset distance from the second electrode layer. Remaining parts of the second material not covered by the multiple second mask layers are removed to obtain the multiple protruding blocks.

Alternatively, the operation of forming the multiple protruding blocks includes the following operations. A sacrificial layer covering part of the piezoelectric layer and the second electrode layer is formed. Multiple grooves exposing part of top surface of the piezoelectric layer in the sacrificial layer are formed, where the multiple grooves are circumferentially arranged around the second electrode layer and have the preset distance from the second electrode layer. A third material layer is formed at bottoms of the multiple grooves and on a top surface of the sacrificial layer. Parts of the third material layer on the top surface of the sacrificial layer and the sacrificial layer are removed to reserve remaining parts of the third material layer at the bottoms of the multiple grooves, so as to obtain the multiple protruding blocks.

In the above schemes, the bulk acoustic resonance structure further includes a first electrode lead, a first conductive thickening layer, a second electrode lead and a second conductive thickening layer.

The operation of forming the first electrode lead and the piezoelectric layer includes the following operations. Both the first electrode layer and the first electrode lead are formed on the reflective structure. Herein the first electrode lead is connected to the first electrode layer and located outside an active area. The first conductive thickening layer covering the first electrode lead is formed. The piezoelectric layer covering the first electrode layer and the first conductive thickening layer is formed.

The operation of forming the second electrode layer includes the following operations. Both the second electrode layer and the second electrode lead are formed on the piezoelectric layer. Herein the second electrode lead is connected to the second electrode layer and located outside the active area.

The method further includes that the second conductive thickening layer covering the second electrode lead is formed.

Embodiments of the present disclosure provide an acoustic device including multiple bulk acoustic resonance structures and a method for manufacturing the same. Each of the multiple bulk acoustic resonance structures includes a substrate. The bulk acoustic resonance structure further includes a reflective structure, a first electrode layer, a piezoelectric layer and a second electrode layer stacked on the substrate in sequence. The bulk acoustic resonance structure further includes multiple protruding blocks located on the piezoelectric layer and circumferentially arranged around the second electrode layer. Herein the multiple protruding blocks have a preset distance from the second electrode layer, and the preset distance depends on a connection manner between the bulk acoustic resonance structure and other ones of multiple bulk acoustic resonance structures. In various embodiments of the present disclosure, the multiple protruding blocks are arranged on the piezoelectric layer, and a distance between the multiple protruding blocks and the second electrode layer can be determined according to the connection manner between the bulk acoustic resonance structure and other ones of the multiple bulk acoustic resonance structures. In other words, the distance between the multiple protruding blocks and the second electrode layer can be adjusted according to requirements for series connection and for parallel connection of circuits in the acoustic device, thereby increasing the global quality factor Q of the acoustic device and improving the performance of the acoustic device.

### BRIEF DESCRIPTION OF THE DRAWINGS

FIG. 1A is a cross-sectional diagram of a bulk acoustic resonance structure according to an embodiment of the present disclosure.

FIG. 1B is a top view diagram of the bulk acoustic resonance structure according to the embodiment of the present disclosure.

FIG. 1C is a diagram of multiple bulk acoustic resonance structures cascaded into steps.

FIG. 1D is a cross-sectional diagram of another bulk acoustic resonance structure according to an embodiment of the present disclosure.

FIG. 1E is a top view diagram of the another bulk acoustic resonance structure according to the embodiment of the present disclosure.

FIG. 2A is a three-dimensional diagram of a protruding block according to an embodiment of the present disclosure.

FIG. 2B is a top view diagram of a bulk acoustic resonance structure without protruding blocks according to an embodiment of the present disclosure.

FIG. 2C is a first diagram of test results of a bulk acoustic resonance structure without the protruding blocks.

FIG. 2D is a second diagram of test results of a bulk acoustic resonance structure without the protruding blocks.

FIG. 3A is a top view diagram of a bulk acoustic resonance structure with protruding blocks according to an embodiment of the present disclosure.

FIG. 3B is a first diagram of test results of different bulk acoustic resonance structures, each with protruding blocks having a different size and different positions according to embodiments of the present disclosure.

FIG. 3C is a second diagram of test results of different bulk acoustic resonance structures, each with protruding blocks having a different size and different positions according to embodiments of the present disclosure.

FIG. 3D is a third diagram of test results of different bulk acoustic resonance structures, each with protruding blocks having a different size and different positions according to embodiments of the present disclosure.

FIG. 3E is a fourth diagram of test results of different bulk acoustic resonance structures, each with protruding blocks having a different size and different positions according to embodiments of the present disclosure.

FIG. 3F is a fifth diagram of test results of different bulk acoustic resonance structures, each with protruding blocks having a different size and different positions according to embodiments of the present disclosure.

FIG. 3G is a sixth diagram of test results of different bulk acoustic resonance structures, each with protruding blocks having a different size and different positions according to embodiments of the present disclosure.

FIG. 3H is a seventh diagram of test results of different bulk acoustic resonance structures, each with protruding blocks having a different size and different positions according to embodiments of the present disclosure.

FIG. 3I is an eighth diagram of test results of different bulk acoustic resonance structures, each with protruding blocks having a different size and different positions according to embodiments of the present disclosure.

FIG. 4A is a first top view diagram of outer contour shapes of some bulk acoustic resonance structures according to embodiments of the present disclosure.

FIG. 4B is a first diagram of test results of some bulk acoustic resonance structures, each having an outer contour of a different size according to embodiments of the present disclosure.

FIG. 4C is a first top view diagram of some bulk acoustic resonance structures, each having an outer contour of a different shape according to embodiments of the present disclosure.

FIG. 4D is a second top view diagram of some bulk acoustic resonance structures, each having an outer contour of a different shape according to embodiments of the present disclosure.

FIG. 4E is a third top view diagram of some bulk acoustic resonance structures, each having an outer contour of a different shape according to embodiments of the present disclosure.

FIG. 4F is a fourth top view diagram of some bulk acoustic resonance structures, each having an outer contour of a different shape according to embodiments of the present disclosure.

FIG. 4G is a fifth top view diagram of some bulk acoustic resonance structures, each having an outer contour of a different shape according to embodiments of the present disclosure.

FIG. 4H is a second diagram of test results of some bulk acoustic resonance structures, each having an outer contour of a different size according to embodiments of the present disclosure.

FIG. 4I is a sixth top view diagram of some bulk acoustic resonance structures, each having an outer contour of a different shape according to embodiments of the present disclosure.

FIG. 4J is a seventh top view diagram of some bulk acoustic resonance structures, each having an outer contour of a different shape according to embodiments of the present disclosure.

FIG. 4K is an eighth top view diagram of some bulk acoustic resonance structures, each having an outer contour of a different shape according to embodiments of the present disclosure.

FIG. 4L is a ninth top view diagram of some bulk acoustic resonance structures, each having an outer contour of a different shape according to embodiments of the present disclosure.

FIG. 4M a tenth top view diagram of some bulk acoustic resonance structures, each having an outer contour of a different shape according to embodiments of the present disclosure.

FIG. 4N is a second top view diagram of outer contour shapes of some bulk acoustic resonance structures according to embodiments of the present disclosure.

FIG. 4O is a third diagram of test results of some bulk acoustic resonance structures, each having an outer contour of a different size according to embodiments of the present disclosure.

FIG. 4P is an eleventh top view diagram of some bulk acoustic resonance structures, each having an outer contour of a different shape according to embodiments of the present disclosure.

FIG. 4Q is a twelfth top view diagram of some bulk acoustic resonance structures, each having an outer contour of a different shape according to embodiments of the present disclosure.

FIG. 4R is a thirteenth top view diagram of some bulk acoustic resonance structures, each having an outer contour of a different shape according to embodiments of the present disclosure.

FIG. 4S is a fourteenth top view diagram of some bulk acoustic resonance structures, each having an outer contour of a different shape according to embodiments of the present disclosure.

FIG. 4T is a fifteenth top view diagram of some bulk acoustic resonance structures, each having an outer contour of a different shape according to embodiments of the present disclosure.

FIG. 5A is a first top view diagram of some bulk acoustic resonance structures, each with a different number of protruding blocks, and corresponding diagrams of test results according to embodiments of the present disclosure.

FIG. 5B is a second top view diagram of some bulk acoustic resonance structures, each with a different number of protruding blocks, and corresponding diagrams of test results according to embodiments of the present disclosure.

FIG. 5C is a third top view diagram of some bulk acoustic resonance structures, each with a different number of protruding blocks, and corresponding diagrams of test results according to embodiments of the present disclosure.

FIG. 5D is a fourth top view diagram of some bulk acoustic resonance structures, each with a different number of protruding blocks, and corresponding diagrams of test results according to embodiments of the present disclosure.

FIG. 5E is a fifth top view diagram of some bulk acoustic resonance structures, each with a different number of protruding blocks, and corresponding diagrams of test results according to embodiments of the present disclosure.

FIG. 5F is a sixth top view diagram of some bulk acoustic resonance structures, each with a different number of protruding blocks, and corresponding diagrams of test results according to embodiments of the present disclosure.

FIG. 5G is a seventh top view diagram of some bulk acoustic resonance structures, each with a different number of protruding blocks, and corresponding diagrams of test results according to embodiments of the present disclosure.

FIG. 5H is an eighth top view diagram of some bulk acoustic resonance structures, each with a different number of protruding blocks, and corresponding diagrams of test results according to embodiments of the present disclosure.

FIG. 5I is a ninth top view diagram of some bulk acoustic resonance structures, each with a different number of protruding blocks, and corresponding diagrams of test results according to embodiments of the present disclosure.

FIG. 6A is a cross-sectional diagram of another bulk acoustic resonance structure according to an embodiment of the present disclosure.

FIG. 6B is a top view diagram of the another bulk acoustic resonance structure according to the embodiment of the present disclosure.

FIG. 7 is a flowchart of implementation of a method for manufacturing a bulk acoustic resonance structure according to an embodiment of the present disclosure.

FIG. 8A is a first cross-sectional diagram of a bulk acoustic resonance structure in process of a method for manufacturing the bulk acoustic resonance structure according to an embodiment of the present disclosure.

FIG. 8B is a second cross-sectional diagram of a bulk acoustic resonance structure in process of a method for manufacturing the bulk acoustic resonance structure according to an embodiment of the present disclosure.

FIG. 8C is a third cross-sectional diagram of a bulk acoustic resonance structure in process of a method for manufacturing the bulk acoustic resonance structure according to an embodiment of the present disclosure.

FIG. 8D is a fourth cross-sectional diagram of a bulk acoustic resonance structure in process of a method for manufacturing the bulk acoustic resonance structure according to an embodiment of the present disclosure.

FIG. 8E is a fifth cross-sectional diagram of a bulk acoustic resonance structure in process of a method for manufacturing the bulk acoustic resonance structure according to an embodiment of the present disclosure.

FIG. 8F is a sixth cross-sectional diagram of a bulk acoustic resonance structure in process of a method for manufacturing the bulk acoustic resonance structure according to an embodiment of the present disclosure.

FIG. 8G is a seventh cross-sectional diagram of a bulk acoustic resonance structure in process of a method for manufacturing the bulk acoustic resonance structure according to an embodiment of the present disclosure.

FIG. 9A is a first cross-sectional diagram of a bulk acoustic resonance structure in process of another method for manufacturing the bulk acoustic resonance structure according to an embodiment of the present disclosure.

FIG. 9B is a second cross-sectional diagram of a bulk acoustic resonance structure in process of another method for manufacturing the bulk acoustic resonance structure according to an embodiment of the present disclosure.

FIG. 10A is a first cross-sectional diagram of a bulk acoustic resonance structure in process of yet another method for manufacturing the bulk acoustic resonance structure according to an embodiment of the present disclosure.

FIG. 10B is a second cross-sectional diagram of a bulk acoustic resonance structure in process of yet another method for manufacturing the bulk acoustic resonance structure according to an embodiment of the present disclosure.

### DETAILED DESCRIPTION

Technical solutions of the present disclosure will be described in more detail below with reference to the drawings and embodiments. Although exemplary embodiments of the present disclosure are illustrated in the drawings, it should be understood that the present disclosure may be implemented in various forms and should not be limited by the embodiments set forth herein. Rather, these embodiments are provided to enable a more thorough understanding of the disclosure and to enable the full scope of the present disclosure to be conveyed to those skilled in the art.

The present disclosure will be described in more detail by way of examples in the following paragraphs with reference to the drawings. Advantages and features of the present disclosure will become clearer according to the following description and claims. It should be noted that all the drawings are illustrated in simplified forms with imprecise proportions, and are only used to conveniently and clearly assist in illustrating the embodiments of the present disclosure.

In the embodiments of the present disclosure, the terms “first”, “second”, and the like are used to distinguish similar objects and are not intended to describe a particular order or priority.

It should be noted that the technical proposals described in the embodiment of the present disclosure can be arbitrarily combined without conflict.

Main parameters of a bulk acoustic resonator include electromechanical coupling coefficient (Kt²), quality factor (Q), and the like. It is essential in design of a filter to increase Q of the resonator with the Kt² of the resonator being kept large. The global quality factor Q (including a factor Qs affecting series connection and a factor Qp affecting parallel connection) of multiple resonators in an acoustic device being higher means that the acoustic device has less energy loss and better device performance. It is essential in design of an acoustic device to choose the appropriate Qs (which affects the series connection) and Qp (which affects the parallel connection). For an acoustic device having multiple resonators connected in series, usage of a high Qs is needed. For an acoustic device having multiple resonators connected in parallel, usage of a high Qp is needed.

According to the connection manner of multiple resonators in the circuit of the acoustic device, it is of practical significance to set appropriate parameters of the resonator structure to make the global quality factor Q (Qs affecting series connection and Qp affecting parallel connection) of the multiple resonators higher in the acoustic device.

In some implementations, in a case that electric energy is applied to an upper electrode and a lower electrode of the bulk acoustic resonator, a piezoelectric layer located between the upper electrode and the lower electrode generates acoustic waves due to a piezoelectric effect. In addition to longitudinal waves, transversal shear waves (transversal shear waves may also be called lateral waves or shear waves) may also be generated in the piezoelectric layer. Existence of the transversal shear waves may affect energy of main longitudinal waves. The transversal shear waves may lead to energy loss and deterioration of the Q of the bulk acoustic resonator. In view of this, a method for increasing the Q of the bulk acoustic resonator is to suppress the transversal shear waves, so as to prevent the transversal shear waves from propagating from an active area to an external area, thus reducing energy leakage.

In some embodiments, protruding blocks are arranged at an edge of the active area on the piezoelectric layer of the bulk acoustic resonator so as to suppress the propagation of the transversal shear waves to the external area, limit the energy in the active area, reduce parasitic resonance and increase the Q. At the same time, the protruding blocks are arranged at suitable positions in the resonator structures according to the connection manner of the multiple resonators in the circuit of the acoustic device, so as to further increase the global quality factor Q (Qs affecting series connection and Qp affecting parallel connection) of the multiple resonators in the acoustic device.

Based on the above, in the embodiments of the present disclosure, suitable resonator structures are set according to the connection manner of the multiple resonators in the circuit of the acoustic device, and the protruding blocks are arranged outside the active area on the piezoelectric layer and near an edge of a second electrode layer, so that the global quality factor Q of the resonators in the acoustic device can be increased.

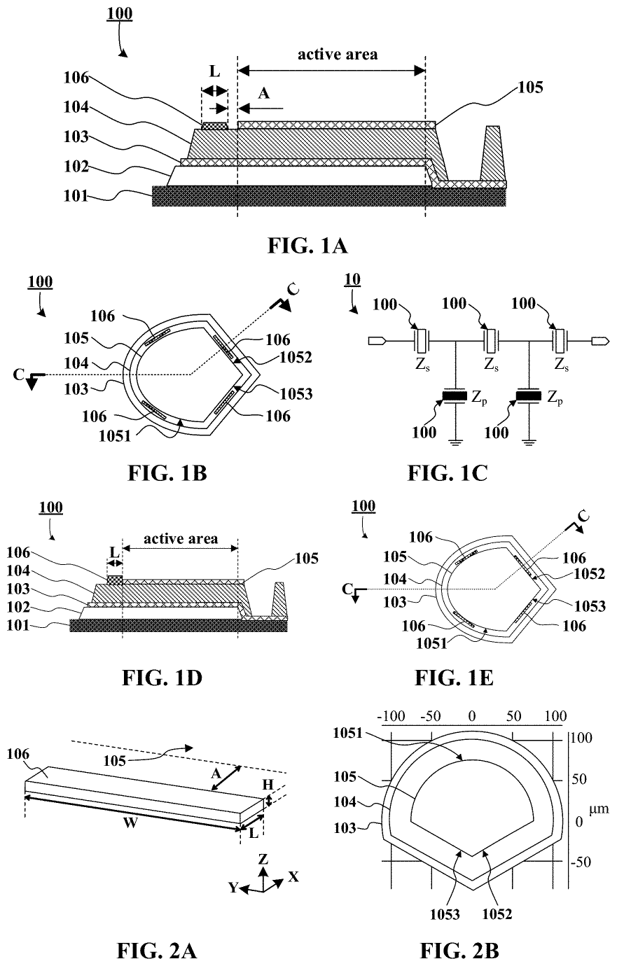

FIG. 1A is a cross-sectional diagram of a bulk acoustic resonance structure according to an embodiment of the present disclosure, and FIG. 1B is a top view diagram of the bulk acoustic resonance structure according to the embodiment of the present disclosure. FIG. 1C is a diagram of multiple bulk acoustic resonance structures cascaded into steps.

As illustrated in FIGS. 1A to 1C, a first aspect of the embodiments of the present disclosure provides an acoustic device 10 including multiple bulk acoustic resonance structures 100. Each of the multiple bulk acoustic resonance structures 100 includes a substrate 101; a reflective structure 102, a first electrode layer 103, a piezoelectric layer 104 and a second electrode layer 105 stacked on the substrate 101 in sequence; and multiple protruding blocks 106 located on the piezoelectric layer 104 and circumferentially arranged around the second electrode layer 105. Herein the multiple protruding blocks 106 have a preset distance A from the second electrode layer 105, and the preset distance A depends on a connection manner between the bulk acoustic resonance structure and other ones of multiple bulk acoustic resonance structures.

It should be noted that in order to intuitively depict the preset distance A between the protruding block 106 and the second electrode layer 105, only the outer contours of the protruding block 106, the first electrode layer 103, the piezoelectric layer and the second electrode layer 105 and their relative positional relations are illustrated in FIG. 1B. The cross-sectional diagram (i.e. FIG. 1A) is a cross-sectional diagram of the bulk acoustic resonance structure (i.e. FIG. 1B) along the C-C cross section direction. In addition, the bulk acoustic resonance structure illustrated in FIGS. 1A and 1B is merely an example of the embodiments of the present disclosure and is not used to limit features of the bulk acoustic resonance structure in the embodiments of the present disclosure. Other examples of bulk acoustic resonance structures of the embodiments of the present disclosure are also illustrated in the following embodiments.

In practical application, a constituent material of the substrate 101 may include silicon (Si), germanium (Ge), and the like.

The first electrode layer 103 may be referred to as a lower electrode, and correspondingly, the second electrode layer 105 may be referred to as an upper electrode. Electrical energy may be applied to a bulk acoustic resonator through the lower electrode and the upper electrode. A constituent material of the first electrode layer 103 and a constituent material of the second electrode layer 105 may be the same, which may specifically include aluminum (Al), molybdenum (Mo), ruthenium (Ru), iridium (Ir), platinum (Pt) or the like.

The piezoelectric layer 104 may generate vibration according to an inverse piezoelectric characteristic so as to convert electrical signals loaded on the first electrode layer 103 and the second electrode layer 105 into acoustic signals, thereby realizing conversion of electrical energy into mechanical energy. In practical application, a constituent material of the piezoelectric layer 104 may include materials with a piezoelectric characteristic (e.g., aluminum nitride, zinc oxide, lithium tantalite, and the like). The constituent material of the piezoelectric layer 104 may also be doped with piezoelectric materials, such as scandium.

The reflective structure 102 is configured to reflect acoustic signals. When the acoustic signals generated by the piezoelectric layer 104 propagates towards the reflective structure 102, the acoustic signal may be totally reflected at the contact surface between the first electrode layer 103 and the reflective structure 102, such that the acoustic signals can be reflected back into the piezoelectric layer 104.

Here, an active area includes a region where the reflective structure 102, the first electrode layer 103, the piezoelectric layer 104 and the second electrode layer 105 overlap in a third direction (as the active area illustrated in FIG. 1A). The third direction is perpendicular to the surface of the substrate 101. It should be understood that the third direction can also understood as the direction in which the first electrode layer 103, the reflective structure 102, the piezoelectric layer 104, and the second electrode layer 105 are stacked on the substrate 101.

The multiple protruding blocks 106 are located on the piezoelectric layer 104 and are circumferentially arranged around the second electrode layer 105. Herein the multiple protruding blocks 106 have a preset distance from the second electrode layer 105.

FIG. 1D is a cross-sectional diagram of another bulk acoustic resonance structure according to an embodiment of the present disclosure, and FIG. 1E is a top view diagram of the another bulk acoustic resonance structure according to the embodiment of the present disclosure. The cross-sectional diagram (i.e. FIG. 1D) is a cross-sectional diagram of the bulk acoustic resonance structure (i.e. FIG. 1E) along the C-C cross section direction. The bulk acoustic resonance structure provided in FIGS. 1D and 1E differs from the bulk acoustic resonance structure provided in FIGS. 1A and 1B in that the multiple protruding blocks 106 illustrated in FIGS. 1D and 1E are located on the piezoelectric layer 104 and arranged circumferentially around the second electrode layer 105, and that the multiple protruding blocks 106 are in contact with the second electrode layer 105.

In some embodiments, a thickness of the protruding blocks in the third direction is greater than a thickness of the second electrode layer in the third direction. The thickness of the protruding blocks is greater than the thickness of the second electrode layer, such that transversal shear waves can be reflected by the impedance difference, thereby reducing a transverse sound wave loss and increasing the Q.

In some embodiments, a constituent material of the protruding blocks may include a metallic material, a dielectric material and a piezoelectric material. The material of the protruding blocks may be metal material molybdenum (Mo) with a high acoustic impedance, a dielectric material silicon dioxide (SiO₂) or a piezoelectric material aluminum nitride (AlN), so as to reduce the transverse sound wave loss and increase the Q.

In a case that there is no resonance in a region located at and under the protruding blocks in the third direction, and there is no extra parasitic resonance, at this time, the protruding blocks can use the metal material Mo with a high acoustic impedance, and the thickness of the protruding blocks are greater than the thickness of the upper electrode, such that the transversal shear waves can be reflected by the acoustic impedance difference, thereby reducing the transverse sound wave loss and increasing the Q.

In a case that the protruding blocks uses the metal material, there would be the resonance in the region located at and under the protruding blocks in the third direction that generates extra parasitic resonance, the protruding blocks can use the dielectric material SiO₂ or the piezoelectric material AlN. The thickness of the protruding blocks cannot be lower than a threshold. An acoustic impedance of the protruding blocks having the thickness of the threshold is equal to an acoustic impedance of region with the resonance. Similarly, transversal shear waves can be reflected by the acoustic impedance difference, thereby reducing a transverse sound wave loss and increasing the Q.

In some embodiments, outer contours of the multiple protruding blocks 106 circumferentially arranged are similar to the shape of the upper electrode and the lower electrode.

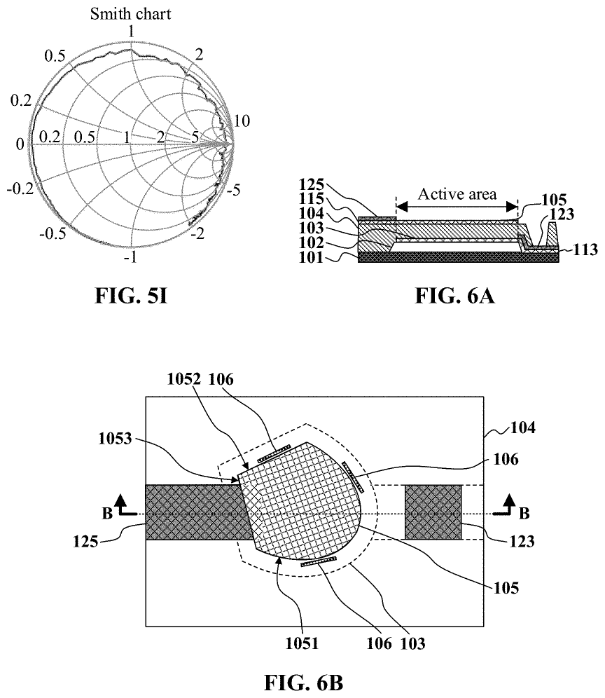

It should be noted that in practical application, the bulk acoustic resonance structure further includes a second electrode lead 115 connected to the second electrode layer 105 (referring to FIGS. 6A and 6B below), and an area covered by the second electrode lead 115 connected to the second electrode layer 105 is not provided with the protruding blocks. Here, in order to more clearly illustrate the preset distance A between the protruding blocks 106 and the second electrode layer 105, as illustrated in FIG. 1B, a first electrode lead 113 of the bulk acoustic resonance structure connected to the first electrode layer 103 and the second electrode lead 115 of the bulk acoustic resonance structure connected to the second electrode layer 105 are omitted (referring to FIG. 6A and FIG. 6B below), and only the outer contour of the first electrode layer 103, the outer contour of the piezoelectric layer 104, the outer contour of the second electrode layer 105 (which is a closed shape including a curve 1051, and two straight lines 1052 and 1053), the outer contour of the protruding blocks 106 are illustrated.

It should be noted that the bulk acoustic resonance structure illustrated in

FIGS. 1A and 1B is only an example of the present disclosure. In practical application, according to the different shapes of the reflective structure 102, the bulk acoustic resonance structure can be specifically divided into a first type of cavity Film Bulk Acoustic Wave Resonator (FBAR), a second type of cavity FBAR, a Solid Mounted Resonator (SMR), and the like. However, the scheme provided in the present disclosure may be applied to the above mentioned different types of bulk acoustic resonance structures.

In some embodiments, when the bulk acoustic resonance structure includes the first type of cavity FBAR, the reflective structure 102 includes a first cavity formed between a protrusion on the first electrode layer 103 and the surface of the substrate 101.

In some embodiments, when the bulk acoustic resonance structure includes the second type of cavity FBAR, the reflective structure 102 includes a second cavity formed between a concavity on the surface of the substrate and the first electrode layer 103.

In some embodiments, when the bulk acoustic resonance structure includes the SMR, the reflective structure 102 includes multiple first dielectric layers and multiple second dielectric layers that differ in acoustic impedance and are alternately stacked.

It should be noted that the reflective structure 102 may be a cavity or a solid structure. When the reflective structure 102 is the cavity, the reflective structure 102 includes the first cavity or the second cavity. When the reflective structure 102 is the solid structure, the reflective structure 102 includes the multiple first dielectric layers and the multiple second dielectric layers alternately stacked. By way of example, here and below, the reflective structure 102 includes the first cavity formed between the protrusion on the first electrode layer 103 and the surface of the substrate 101.

In some embodiments, in a case that the bulk acoustic resonance structure 100 is connected to a branch of the acoustic device 10 in series, the preset distance A is less than or equal to a first distance.

In a case that the bulk acoustic resonance structure 100 is connected to the branch of the acoustic device 10 in parallel, the preset distance A is greater than the first distance.

As illustrated in FIG. 1C, the acoustic device 10 generally includes multiple bulk acoustic resonance structures 100, the multiple bulk acoustic resonance structures are generally cascaded in a ladder type. The acoustic device 10 with ladder-type cascaded bulk acoustic resonance structures is composed of multiple bulk acoustic resonance structures 100 electrically connected in series or in parallel. A preset bandpass characteristic can be obtained by adjusting a resonant frequency of resonance structures Zs connected in series and a resonant frequency of resonance structures Zp connected in parallel. Under action of the resonance structures Zs connected in series and the resonance structures Zp connected in parallel, the acoustic device 10 realizes the function of allowing waves of a specific frequency band (here, the specific frequency band is also referred to as “bandwidth”) to pass through, and while shielding functions of the device in other frequency bands, so as to improve Qp (which affects the parallel connection) and Qs (which affects the series connection).

In a case that the bulk acoustic resonance structure 100 is connected to a branch of the acoustic device 10 in series (referring to the resonance structures Zs in FIG. 1C), the preset distances A is less than or equal to a first distance, and Qs rises significantly. At this time, Qp decreases to a certain extent. In a case that the bulk acoustic resonance structure 100 is connected to a branch of the acoustic device 10 in parallel (referring to the resonance structures Zp in FIG. 1C), the preset distance A is greater than the first distance, and Qp rises significantly. At this time, Qs decreases to a certain extent. In other words, the preset distance A between the protruding blocks 106 and the second electrode layer 105 may be adjusted according to requirements of series connection and parallel connection in the circuit of the multiple acoustic resonance structures, so as to increase global quality factor Q of the multiple acoustic resonance structures.

Here, the preset distance A may be adjusted according to the actual situation, and an example of the preset distance A is given below.

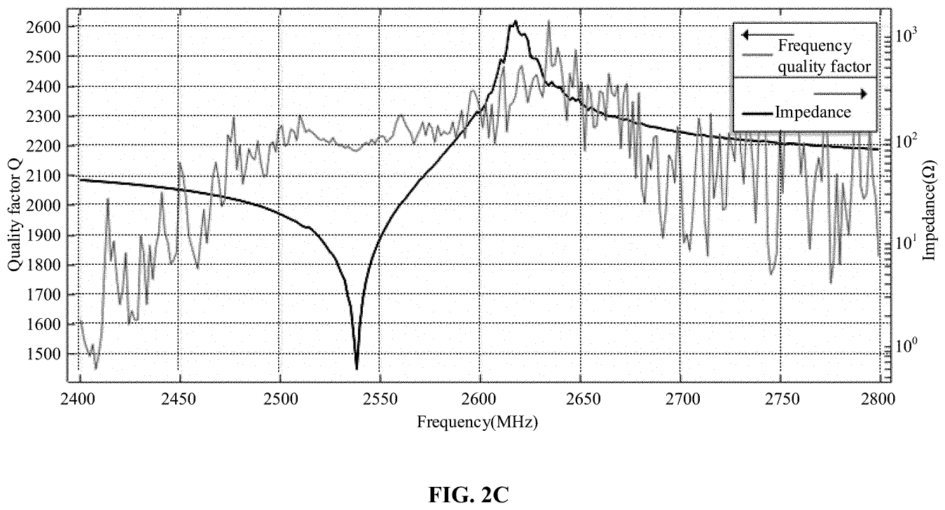

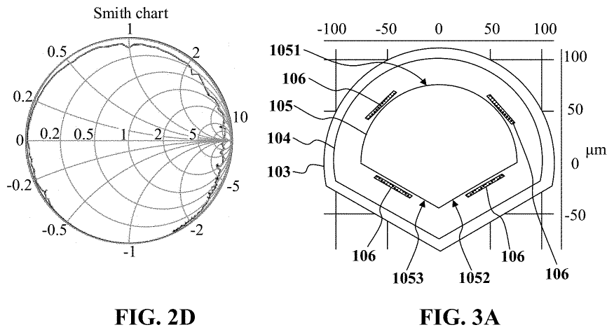

FIG. 2A is a three-dimensional diagram of a protruding block according to an embodiment of the present disclosure, and FIG. 2B is a top view diagram of a bulk acoustic resonance structure according to the embodiment of the present disclosure. FIGS. 2C and 2D are diagrams of test results of a bulk acoustic resonance structure without protruding blocks.

As illustrated in FIG. 2A, in some embodiments, the protruding block has a size L of 0.5 μm to 4 μm in a first direction, a size W of 10 μm to 40 μm in a second direction, and a size H of 0.1 μm to 1 μm in a third direction. Herein the first direction is a direction from an edge of the second electrode layer to a middle of the second electrode layer (referring to FIG. 1B). The second direction is perpendicular to the first direction and parallel to the surface of the substrate. The third direction is perpendicular to the surface of the substrate (referring to FIG. 1A). The protruding block may have a shape of a cuboid, or may have any other regular or irregular shape. It should be noted that when the protruding block has any other regular or irregular shape, the size can be understood as the maximum size. For example, the protruding block has the size L of 0.5 μm to 4 μm in the first direction, which can be understood as the protruding block having the maximum size of 0.5 μm to 4 μm in the first direction.

As illustrated in FIG. 2B, in some embodiments, each of the outer contour of the first electrode layer 103, the outer contour of the piezoelectric layer 104 and the outer contour of the second electrode layer 105 may be a closed shape including a curve and two straight lines. For example, the outer contour of the second electrode layer is the closed shape including a curve 1051, and two straight lines 1052 and 1053. In some embodiments, the area of the outer contour of the second electrode layer 105 can be adjusted according to the actual situation.

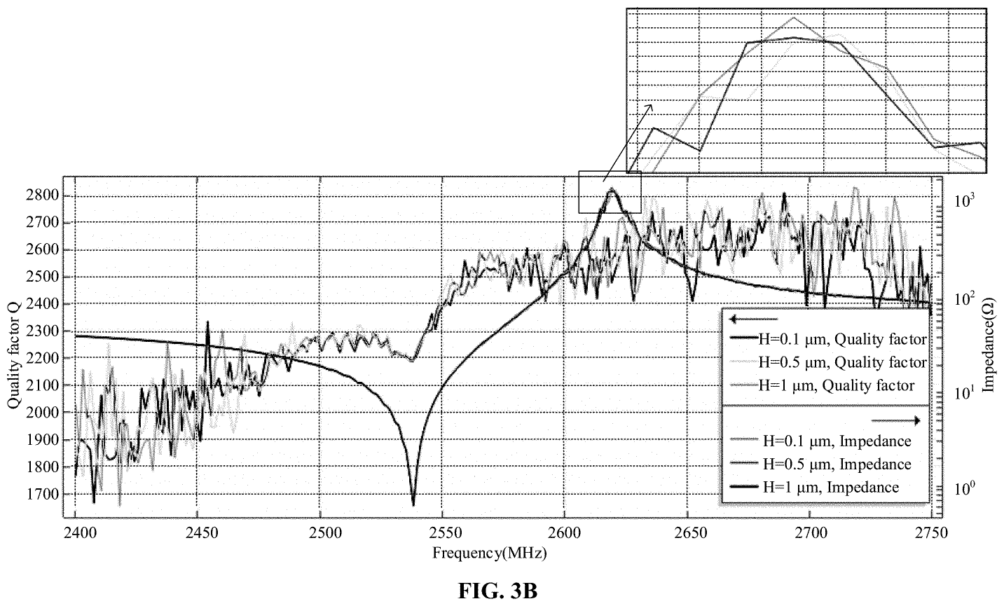

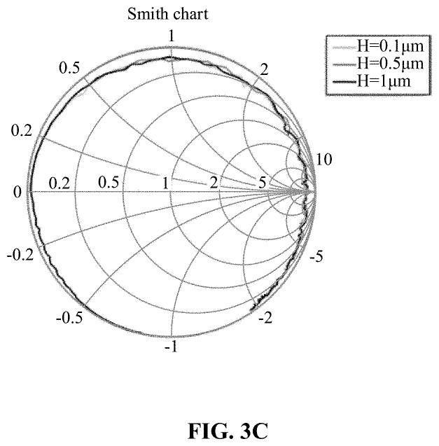

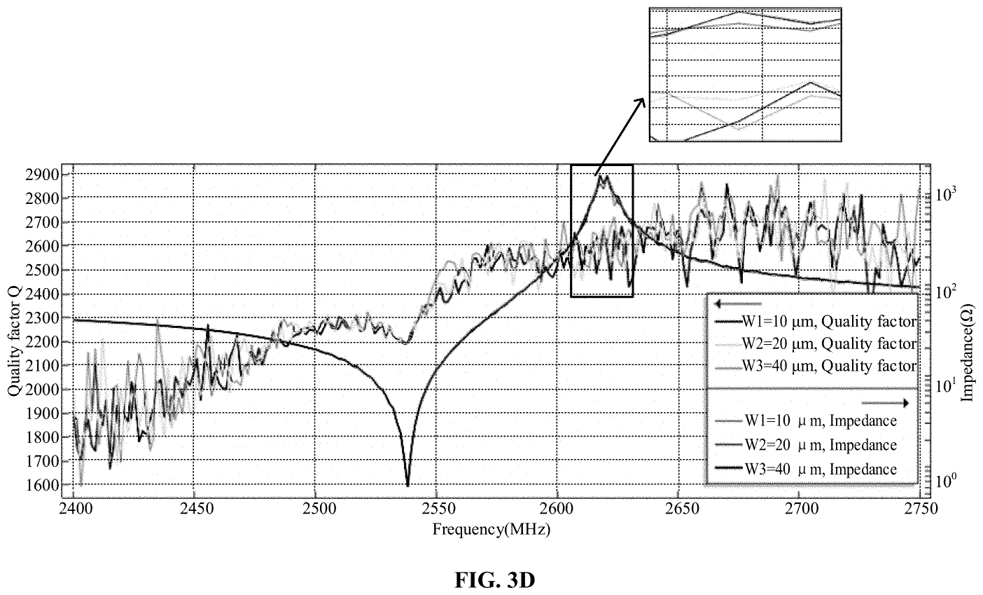

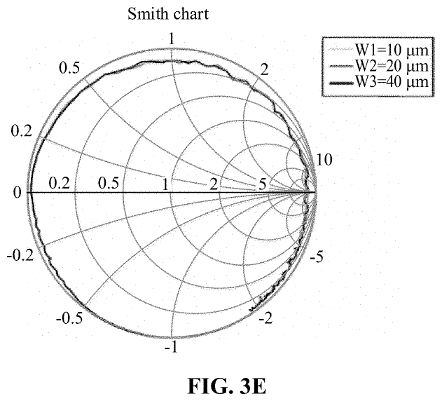

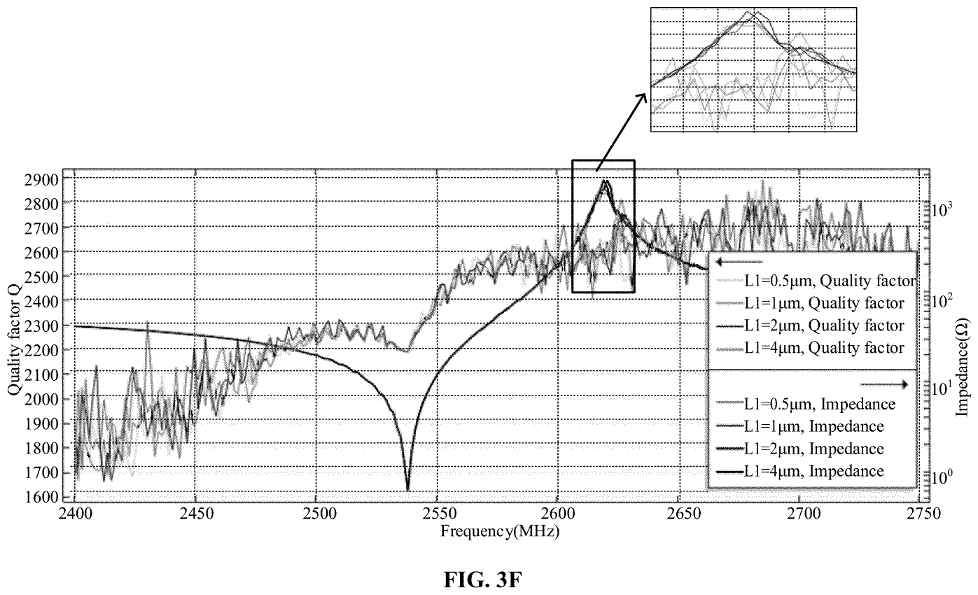

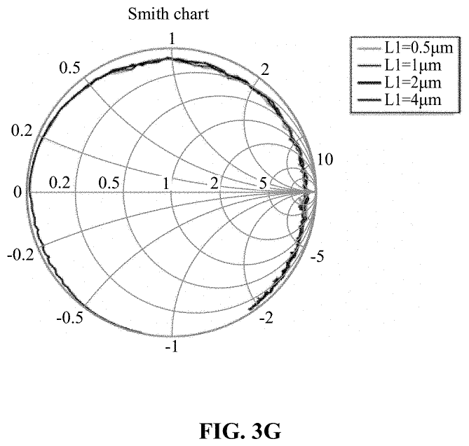

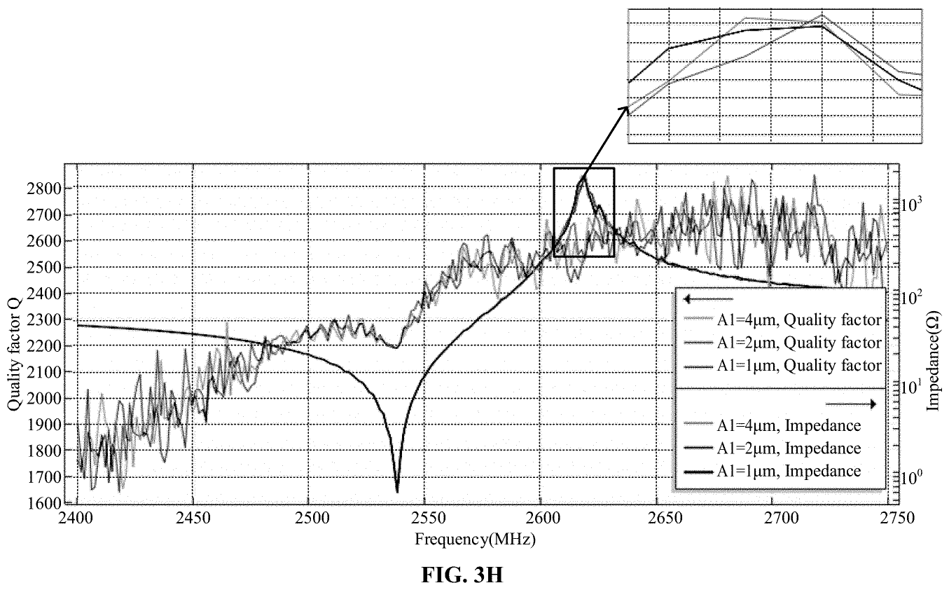

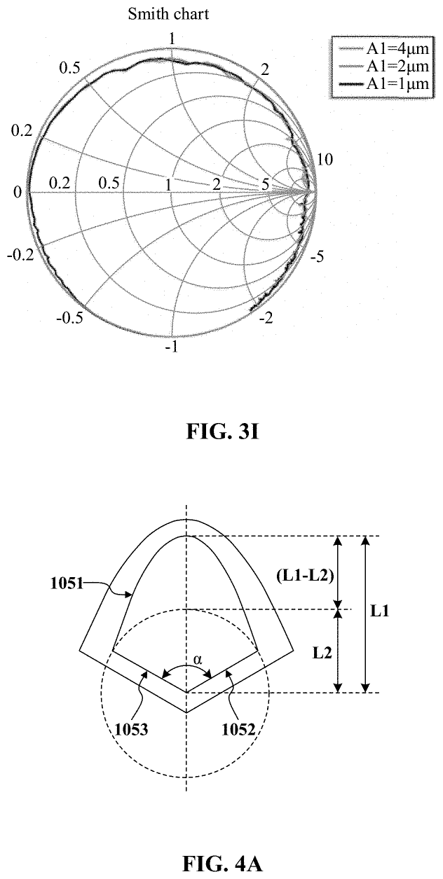

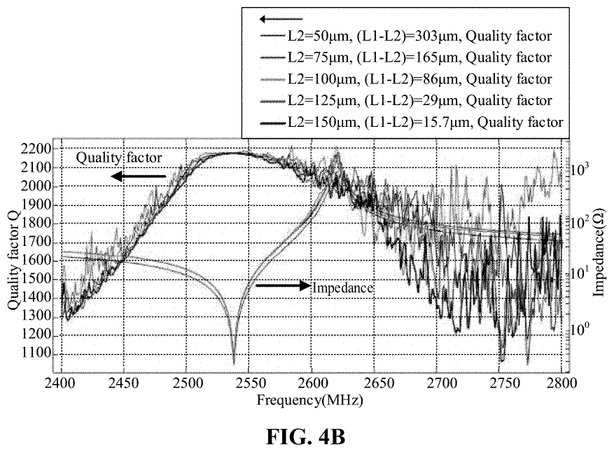

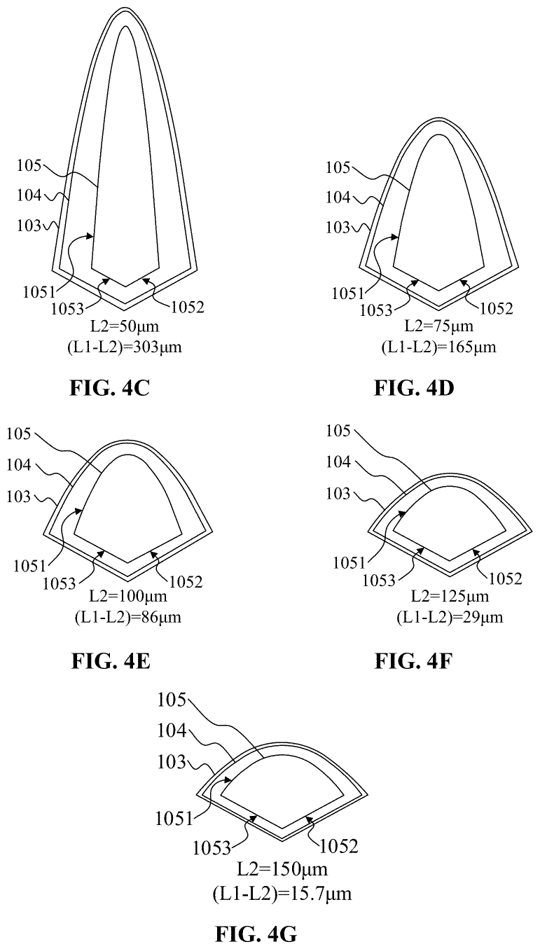

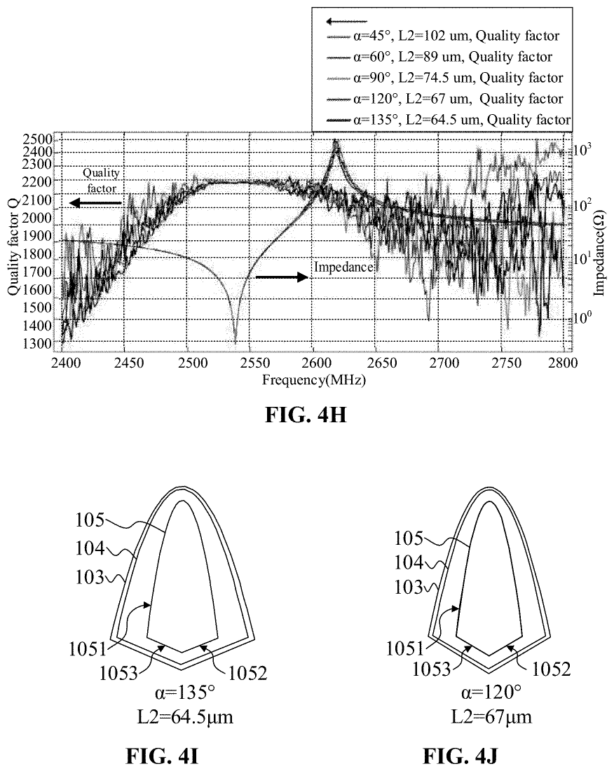

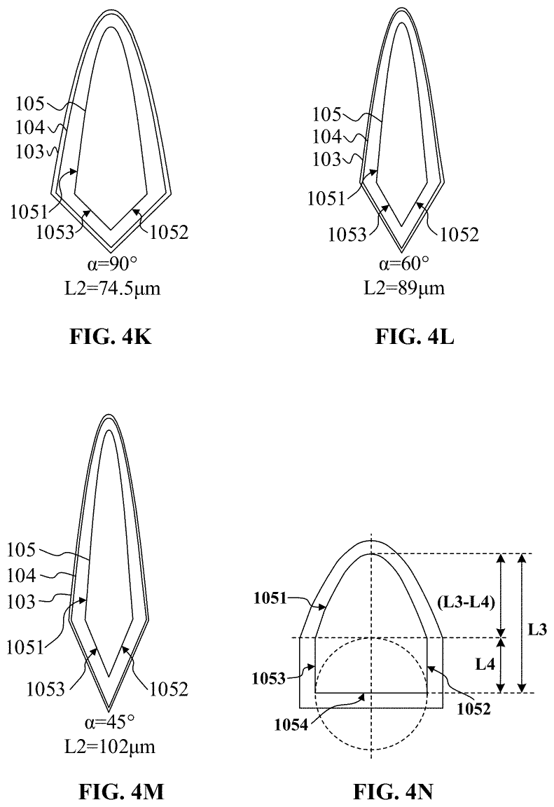

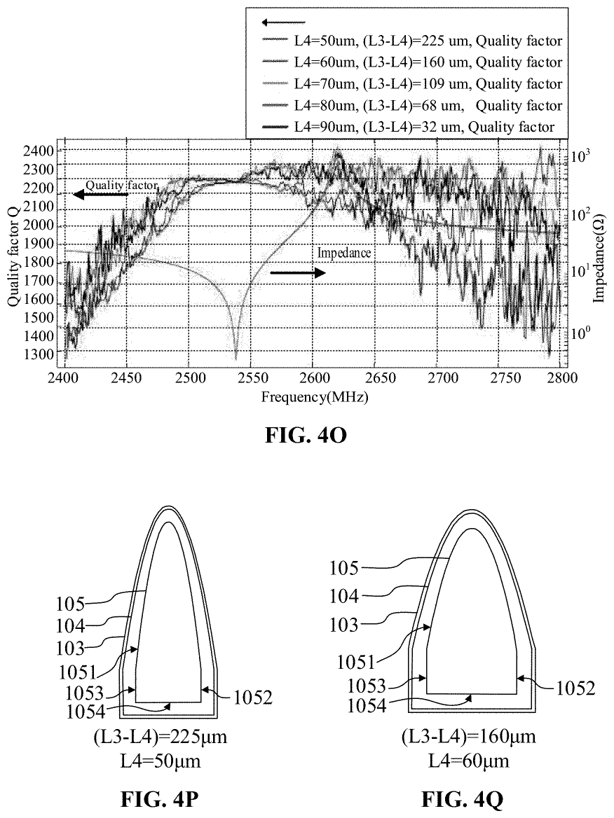

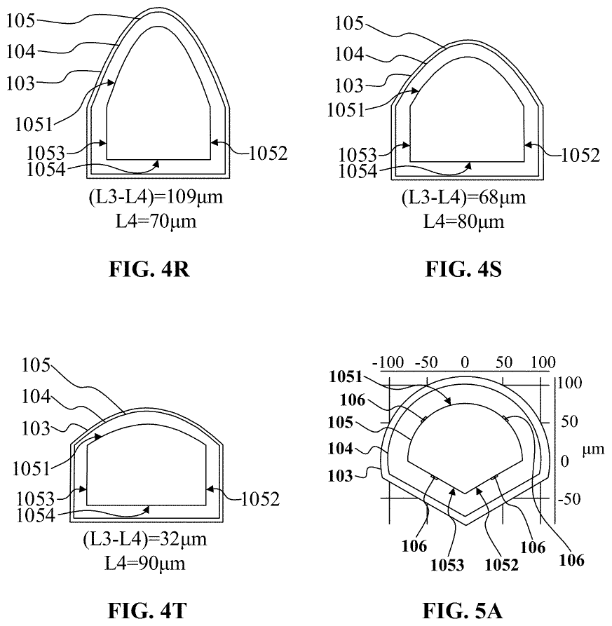

It should be noted that the area of the outer contour of the second electrode layer in the bulk acoustic resonance structure illustrated in FIGS. 2B and 3A is only an example of the embodiments of the present disclosure and is not intended to limit the characteristics of the bulk acoustic resonance structure in the embodiments of the present disclosure. The outer contour of the bulk acoustic resonance structure illustrated in FIGS. 2B and 3A includes a closed shape formed by the curve and two straight lines, which is only an example of the embodiments of the present disclosure, and is not intended to limit the characteristics of the bulk acoustic resonance structure in the embodiments of the present disclosure. Other outer contour shapes and areas of the bulk acoustic resonance structure are described below in FIGS. 4A to 4T.

FIG. 2C illustrates test results of the quality factor Q and the impedance of a bulk acoustic resonance structure (herein and hereinafter referred to as an original structure) without protruding blocks, and FIG. 2D illustrates a smith chart of the original structure without protruding blocks. As illustrated in FIGS. 2C and 2D, Qs and Qp of the original structure are 2182 and 2381, respectively. Here the Qs and the Qp of the original structure may serve as a comparison group in the following embodiments.

FIG. 3A is a top view diagram of a bulk acoustic resonance structure with protruding blocks according to an embodiment of the present disclosure.

As illustrated in FIG. 3A, in some embodiments, the multiple protruding blocks 106 are uniformly arranged in the circumferential direction around the outer contour of the second electrode layer 105. In some embodiments, the number of the multiple protruding blocks 106 may be 4, 8 or 16.

Exemplarily, the outer contour of the second electrode layer 105 is the closed shape including the curve 1051, and two straight lines 1052 and 1053. The number of the multiple protruding blocks 106 is 4. Herein, two of protruding blocks are uniformly arranged in the circumferential direction around the outer contour of the curve 1051 of the second electrode layer. One of the protruding blocks is uniformly arranged in the circumferential direction around the outer contour of the straight line 1052 of the second electrode layer. One of protruding blocks is uniformly arranged in the circumferential direction around the outer contour of the straight line 1053 of the second electrode layer.

It should be noted that, here and below, the number of the multiple protruding blocks 106 being 4 is taken as an example only for description of the embodiments of the present disclosure, and is not intended to limit the scope of the present disclosure.

FIGS. 3B and 3C are diagrams of test results of different bulk acoustic resonance structure, each with protruding blocks having a different size in the third direction, according to the embodiments of the present disclosure.

FIG. 3B illustrates test results of the quality factors Q and the impedances of different bulk acoustic resonance structures, each with protruding blocks having a respective one of the following sizes in the third direction: H=0.1 μm, H=0.5 μm, H=1.0 μm. FIG. 3C illustrates a smith chart of the different bulk acoustic resonance structures, each with the protruding blocks having a respective one of the following sizes in the third direction: H=0.1 μm, H=0.5 μm, H=1.0 μm. Herein the Qs and the Qp of the original structure may serve as the comparison group, and the number of the protruding blocks 106 is 4. Each of the protruding blocks 106 has a size W of 20 μm in the second direction. The distance A between each of the protruding blocks 106 and the second electrode layer in the first direction is 2 μm. Each of the protruding blocks 106 has the size L of 2 μm in the first direction.

As can be seen from FIGS. 3B and 3C, and table 1 below, compared with the original structure, introduction of the protruding blocks into the bulk acoustic resonance structure can significantly increase the Q (both the Qs and the Qp are significantly improved). The Q has a best value and the parasitic resonance is the smallest when the size H of the protruding blocks in the third direction is equal to 0.5 μm.

TABLE 1

| | Original | | | |
|---|---|---|---|---|
| | structure | H = 0.1 μm | H = 0.5 μm | H = 1.0 μm |
| Qs | 2182 | 2188 | 2191 | 2190 |
| Qp | 2381 | 2477 | 2564 | 2555 |

FIGS. 3D and 3E are diagrams of test results of different bulk acoustic resonance structures, each with protruding blocks having a different size in the second direction, according to the embodiments of the present disclosure.

FIG. 3D illustrates test results of the quality factors Q and the impedances of different bulk acoustic resonance structures, each with the protruding blocks having a respective one of the following sizes in the second direction: W=10 μm, W=20 μm, W=40 μm. FIG. 3E illustrates a smith chart of the different bulk acoustic resonance structures, each with the protruding blocks having a respective one of the following sizes in the second direction: W=10 μm, W=20 μm, W=40 μm. Herein the Qs and the Qp of the original structure may serve as the comparison group, and the number of the protruding blocks 106 is 4. Each of the protruding blocks 106 has the size H of 0.5 μm in the third direction. The distance A between each of the protruding blocks 106 and the second electrode layer in the first direction is 2 μm. Each of the protruding blocks 106 has the size L of 2 μm in the first direction.

As can be seen from FIGS. 3D and 3E, and table 2 below, compared with the original structure, the introduction of the protruding blocks into the bulk acoustic resonance structure can significantly increase the Q (both the Qs and the Qp are significantly improved). The Q has a best value when W is equal to 20 μm, and the value of the Q comes second when W is equal to 10 μm. The value of the Q is the third when W is equal to 40 μm. Regarding influence on the resonance performance, the Q has a best value when W is equal to 10 μm and 40 μm, and the value of the Q comes second when W is equal to 20 μm. The protruding blocks has the preferable size W of 10 μm in the second direction.

TABLE 2

| | Original | | | |
|---|---|---|---|---|
| | structure | W = 10 μm | W = 20 μm | W = 40 μm |
| Qs | 2182 | 2189 | 2193 | 2189 |
| Qp | 2381 | 2558 | 2574 | 2535 |

FIGS. 3F and 3G are diagrams of test results of different bulk acoustic resonance structure, each with protruding blocks having a different size in the first direction, according to the embodiments of the present disclosure.

FIG. 3F illustrates test results of the quality factors Q and the impedances of bulk acoustic resonance structures, each with the protruding blocks having a respective one of the following sizes in the first direction: L=10 μm, L=20 μm, L=40 μm. FIG. 3G illustrates a smith chart of the bulk acoustic resonance structures, each with the protruding blocks having a respective one of the following sizes in the first direction: L=10 μm, L=20 μm, L=40 μm. Herein the Qs and the Qp of the original structure may serve as the comparison group, and the number of the protruding blocks 106 is 4. Each of the protruding blocks 106 has a size H of 0.5 μm in the third direction. The distance A between each of the protruding blocks 106 and the second electrode layer in the first direction is 2 μm. Each of the protruding blocks 106 has a size W of 2 μm in the second direction.

As can be seen from FIGS. 3F and 3G, and table 3 below, compared with the original structure, the introduction of the protruding blocks into the bulk acoustic resonance structure can significantly increase the Q (both the Qs and the Qp are significantly improved). The smaller the size of the protruding blocks in the first direction is, the higher the Q is, but the worse the resonance performance is. Each of the protruding blocks has the preferable size L of 2 μm in the first direction.

TABLE 3

| | Original | | | | |
|---|---|---|---|---|---|
| | structure | L = 0.5 μm | L = 1 μm | L = 2 μm | L = 4 μm |
| Qs | 2182 | 2188 | 2188 | 2187 | 2187 |
| Qp | 2381 | 2631 | 2596 | 2583 | 2547 |

FIGS. 3H and 3I are diagrams of test results of different bulk acoustic resonance structures, each with protruding blocks having a different distance from the second electrode layer in the first direction according to the embodiments of the present disclosure.

Based on this, it is preferable that each of the protruding blocks has a size L of 2 μm in the first direction, and a size W of 10 μm in the second direction, and a size H of 0.5 μm in the third direction.

In some embodiments, the first distance can be set according to actual requirements. In some embodiments, the first distance is greater than or equal to zero and is less than a spacing between the outer contour of the piezoelectric layer and the outer contour of the second electrode layer. In some embodiments, the first distance is 4 μm.

FIG. 3H illustrates test results of the quality factor Q and the impedance of different bulk acoustic resonance structures, each with protruding blocks having a respective one of the following sizes in the first direction: A=1 μm, A=2 μm, A=4 μm. FIG. 3G illustrates a smith chart of the different bulk acoustic resonance structures, each with the protruding blocks having a respective one of the following sizes in the first direction: A=1 μm, A=2 μm, A=4 μm. Herein the Qs and the Qp of the original structure may serve as the comparison group, and the number of the protruding blocks 106 is 4. Each of the protruding blocks 106 has a size H of 0.5 μm in the third direction, a size W of 10 μm in the second direction, and a size L of 2 μm in the first direction.

As can be seen from FIGS. 3H and 3I, and table 4 below, compared with the original structure, the introduction of the protruding blocks into the bulk acoustic resonance structure can significantly increase the Q (both the Qs and the Qp are significantly improved). The longer the distance between the protruding blocks and the second electrode layer in the first direction is, the higher the Q is. In practical application, the distance A between the protruding blocks and the second electrode layer in the first direction is greater than or equal to zero and is less than the spacing between the outer contour of the piezoelectric layer 104 and the outer contour of the second electrode layer 105 in the first direction. Preferably, the distance A between the protruding blocks and the second electrode layer in the first direction is 4 μm.

TABLE 4

| | Original | | | |
|---|---|---|---|---|
| | structure | A = 1 μm | A = 2 μm | A = 4 μm |
| Qs | 2182 | 2190 | 2188 | 2187 |
| Qp | 2381 | 2527 | 2540 | 2552 |

It should be noted that the distances between the multiple protruding blocks and the second electrode layer can be the same or different. Exemplarily, the distances A between the multiple protruding blocks and the second electrode layer are all the same.

FIGS. 4A and 4N are top view diagrams of outer contour shapes of some bulk acoustic resonance structures according to the embodiments of the present disclosure. FIGS. 4B, 4H and 4O are diagrams of test results of some bulk acoustic resonance structures, each having an outer contour of a different size according to embodiments of the present disclosure. FIGS. 4C to 4G, FIGS. 4I to 4M and FIGS. 4P to 4T are top view diagrams of some bulk acoustic resonance structures, each having an outer contour of a different shape according to embodiments of the present disclosure. It should be noted that in order to intuitively describe the outer contour of the second electrode layer, only the outer contours of the first electrode layer, the piezoelectric layer and the second electrode layer are illustrated in FIG. 4A, FIG. 4N, FIGS. 4C to 4G, FIGS. 4I to 4M and FIGS. 4P to 4T. The bulk acoustic resonance structure illustrated in FIG. 4A, FIG. 4N, FIGS. 4C to 4G, FIGS. 4I to 4M and FIGS. 4P to 4T is merely an example of the embodiments of the present disclosure and is not used to limit characteristics of the bulk acoustic resonance structure in the embodiments of the present disclosure. Other examples of bulk acoustic resonance structures of the embodiments of the present disclosure are also illustrated in the following embodiments.

In some embodiments, an outer perimeter of the second electrode layer is of a closed shape including a curve and two or more straight lines.

As illustrated in FIG. 4A, in some embodiments, the closed shape includes a curve 1051 and two straight lines 1052 and 1053 of a same length, and the two straight lines 1052 and 1053 form an angle of 0 degree to 180 degrees.

A maximum distance between the curve 1051 and an intersection of the two straight lines 1052 and 1053 is L1, and each of the two straight lines 1052 and 1053 has a length of L2. Herein a ratio of L2 to (L1−L2) ranges from 1:0.1 to 1:6.

In the embodiments, the two straight lines form an angle of 120 degrees, and the ratio of L2 to (L1−L2) ranges from 1:0.1 to 1:6.

FIG. 4B shows the test results of the quality factors Q and the impedances under the condition that the area of the outer contour of the second electrode layer remains unchanged and the ratio of L2 to (L1−L2) varies. Specifically, the outer contour of the second electrode layer of the bulk acoustic resonance structure includes a curve and two straight lines. Under the condition that a resonance area is 20000 μm², the two straight lines form an angle of 120 degrees and the ratio of L2 to (L1−L2) is 1:6, 1:2.2, 1:0.86, 1:0.23 and 1:0.1 respectively, the influences on the performance of the bulk acoustic resonance structure are illustrated in Table 5 and FIG. 4B. With the same resonance area, the smaller the ratio of L2 to (L1−L2) is, the higher the Qp is.

FIGS. 4C to 4G illustrates comparison results of the outer contour characteristics of the bulk acoustic resonance structure under the condition that the area of the outer contour remains unchanged, the two straight lines form an angle of 120 degrees and the ratio of L2 to (L1−L2) is 1:6, 1:2.2, 1:0.86, 1:0.23 and 1:0.1 respectively. With the same resonance area, the smaller the ratio of L2 to (L1−L2) is, the higher the Qp is. When the outer contour characteristics of the bulk acoustic resonance structure is of a prolate shape (as illustrated in FIG. 4C), the bulk acoustic resonance structure has an optimum performance.

TABLE 5

| | L2 = 50 μm | L2 = 75 μm | L2 = 100 μm | L2 = 125 μm | L2 = 150 μm |
|---|---|---|---|---|---|
| | (L1 − L2) = 303 μm | (L1 − L2) = 165 μm | (L1 − L2) = 86 μm | (L1 − L2) = 29 μm | (L1 − L2) = 15.7 μm |
| L2/(L1 − L2) | 1:6 | 1:2.2 | 1:0.86 | 1:0.23 | 1:0.1 |
| Qs | 2174 | 2176 | 2176 | 2176 | 2175 |
| Qp | 2097 | 2017 | 2011 | 1991 | 1985 |

In some specific embodiments, the ratio of L2 to (L1−L2) is 1:3, and the two straight lines form an angle of 45 degrees to 135 degrees.

FIG. 4H shows the test results of quality factor Q and the impedance under the condition that the area of the outer contour of the second electrode layer remains unchanged, the ratio of L2 to (L1−L2) is 1:3, and the angle formed by the two straight lines varies. Specifically, the outer contour of the second electrode layer of the bulk acoustic resonance structure includes a curve and two straight lines. Under the condition that the resonance area is 20000 μm², the ratio of L2 to (L1−L2) is 1:3 and the two straight lines form the angles of 45 degrees, 60 degrees, 90 degrees, 120 degrees and 135 degrees respectively, the influences on the performance of the bulk acoustic resonance structure are illustrated in Table 6 and FIG. 4H. With the same resonance area, the smaller the angle formed by the two straight lines is, the higher the Qp is.

FIGS. 4I to 4M illustrates comparison results of the outer contour characteristics of the bulk acoustic resonance structure under the condition that the area of the outer contour remains the same, the ratio of L2 to (L1−L2) is 1:3 and the two straight lines form the angles of 135 degrees, 120 degrees, 90 degrees, 60 degrees and 45 degrees respectively. With the same resonance area, the smaller angle formed by the two straight lines is, the higher the Qp is. When the outer contour characteristics of the bulk acoustic resonance structure is of a prolate shape (as illustrated in FIG. 4M), the bulk acoustic resonance structure has an optimum performance.

TABLE 6

| | α = 45° | α = 60° | Alpha = 90° | α = 120° | α = 135° |
|---|---|---|---|---|---|
| L2 | 102 μm | 89 μm | 74.5 μm | 67 μm | 64.5 μm |
| Qs | 2180 | 2176 | 2176 | 2176 | 2177 |
| Qp | 2125 | 2097 | 2013 | 2078 | 2060 |

As illustrated in FIG. 4N, in some embodiments, the closed shape includes a curve 1051 and a first straight line 1052, a second straight line 1053 and a third straight line 1054. The first straight line 1052 is connected to one end of the curve 1051 and one end of the third straight line 1054, and the second straight line 1053 is connected to another end of the curve 1051 and another end of the third straight line 1054. The first straight line 1052 and the third straight line 1054 form an angle of 90 degrees, and the second straight line 1053 and the third straight line 1054 form an angle of 90 degrees.

A maximum distance between the curve 1051 and the third straight line 1054 is L3. Each of first straight line 1052 and the second straight line 1053 has a length of L4, and a ratio of (L3−L4) to L4 ranges from 0.36:1 to 4.5:1. In some specific embodiments each of the length of the first line 1052 and the length of the second line 1053 is less than the length of the third line 1054. Specifically each of the length of the first line 1052 and the length of the second line 1053 may be half the length of the third line 1054.

FIG. 4O shows the test results of the quality factor Q and the impedance under the condition that the area of the outer contour of the second electrode layer remains unchanged and the ratio of (L3−L4) to L4 varies. Specifically, the outer contour of the second electrode layer of the bulk acoustic resonance structure includes a curve and three straight lines. Under the condition that the resonance area remains 20000 μm², and the ratio of (L3−L4) to L4 is 4.5:1, 2.7:1, 1.6:1, 0.85:1 and 0.36:1 respectively, influences on the performance of the bulk acoustic resonance structure is illustrated in Table 7 and FIG. 4O. With the same resonance area, the ratio of (L3−L4) to L4 has no significant linear relationship with the performance of the bulk acoustic resonance structure. However, when the ratio of (L3−L4) to L4 is less than 1.6:1, the Qp is significantly increased, and the effect of the bulk acoustic resonance structure is better than the effect of the bulk acoustic resonance structures illustrated in Tables 5 and 6, and FIGS. 4B, 4C, 4H and 4M.

FIGS. 4P to 4T illustrates comparison results of the outer contour characteristics of the bulk acoustic resonance structure under the condition that the area of the outer contour remains the same, the two straight lines form an angle of 120 degrees and the ratio of L2 to (L1−L2) is 4.5:1, 2.7:1, 1.6:1, 0.85:1 and 0.36:1 respectively. With the same resonance area, when the ratio of (L3−L4) to L4 is less than 1.6:1 (as illustrated in FIGS. 4S and 4T), the Qp is significantly increased, and the effect the bulk acoustic resonance structure is better than the effect of the bulk acoustic resonance structures illustrated in FIGS. 4C and 4M.

TABLE 7

| | (L3 − L4) = 225 μm | (L3 − L4) = 160 μm | (L3 − L4) = 109 μm | (L3 − L4) = 68 μm | (L3 − L4) = 32 μm |
|---|---|---|---|---|---|
| | L4 = 50 μm | L4 = 60 μm | L4 = 70 μm | L4 = 80 μm | L4 = 90 μm |
| (L3 − L4)/L4 | 4.5:1 | 2.7:1 | 1.6:1 | 0.85:1 | 0.36:1 |
| Qs | 2176 | 2176 | 2179 | 2179 | 2178 |
| Qp | 2075 | 2076 | 2262 | 2189 | 2295 |

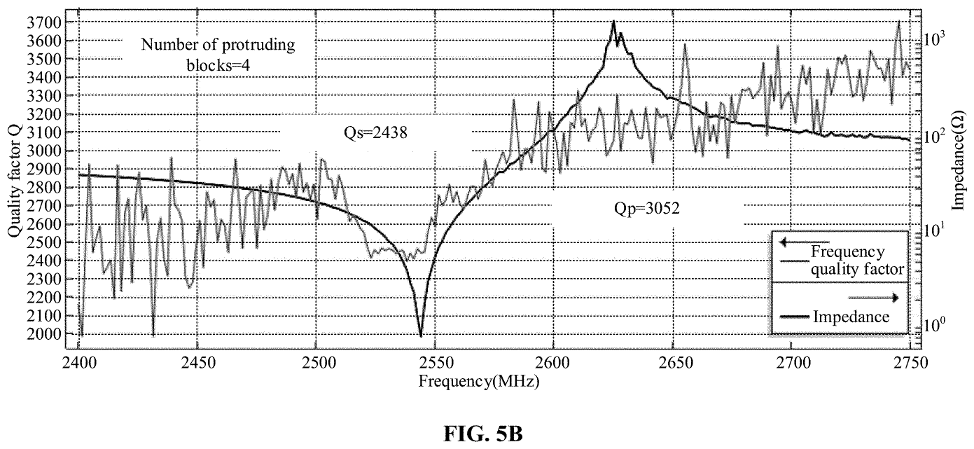

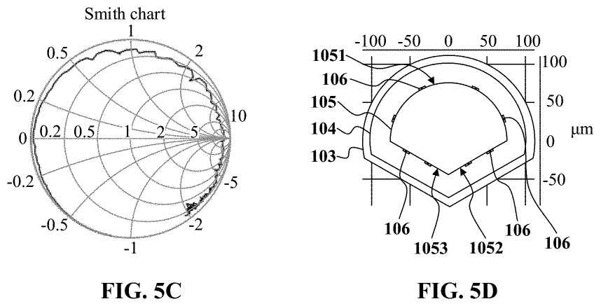

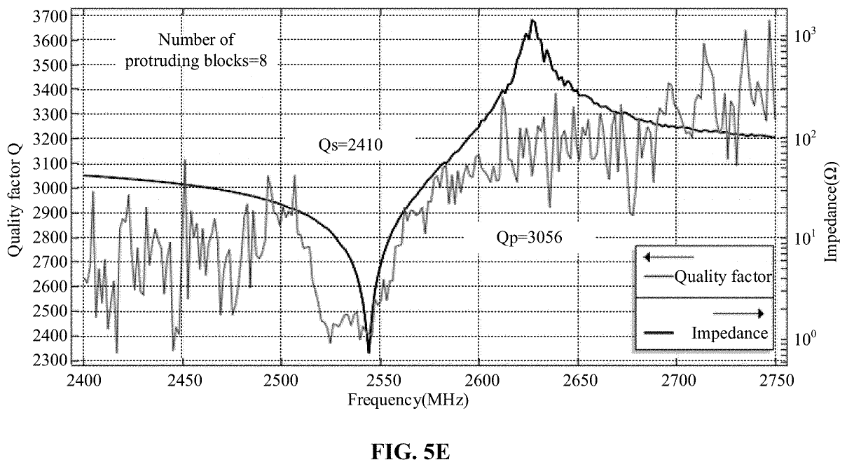

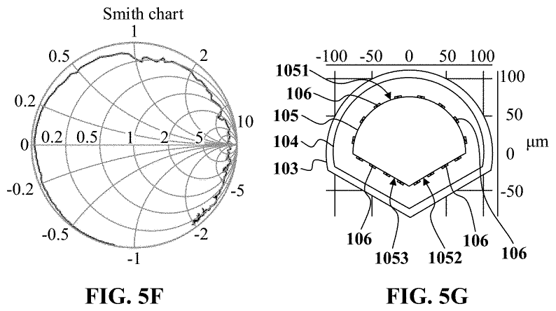

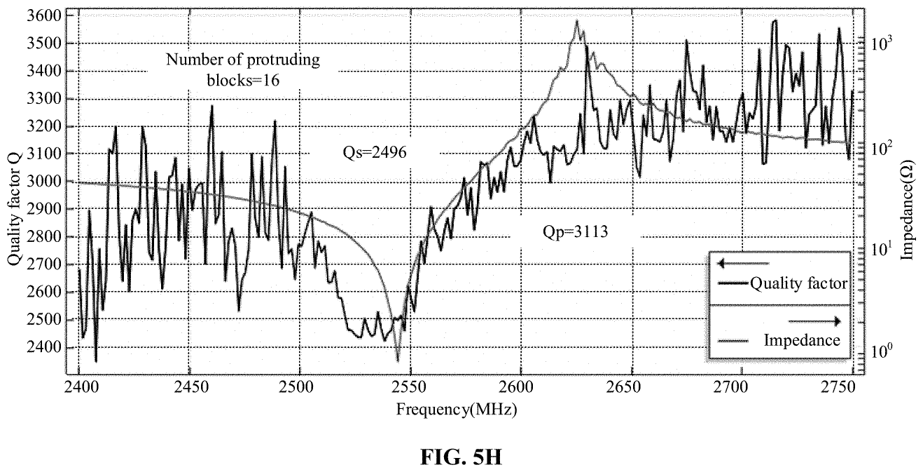

FIGS. 5A to 5I are top view diagrams of some bulk acoustic resonance structures, each with a different number of protruding blocks and corresponding test results according to embodiments of the present disclosure.

Specifically, the outer contour of the second electrode layer of the bulk acoustic resonance structure includes a curve and two straight lines. Under the condition that the resonance area remains 20000 μm² and the protruding blocks are in contact with the second electrode layer, influences of the different numbers of protruding blocks on performance of the bulk acoustic resonance structure are illustrated in FIGS. 5A to 5C, FIGS. 5D to 5F and FIGS. 5 to 5I. FIGS. 5A to 5C are top view diagrams of the bulk acoustic resonance structure with 4 protruding blocks and diagrams of corresponding test results. FIGS. 5D to 5F are top view diagrams of the bulk acoustic resonance structure with 8 protruding blocks and diagrams of corresponding test results. FIGS. 5G to 5I are top view diagrams of the bulk acoustic resonance structure with 16 protruding blocks and diagrams of corresponding test results. The test results are illustrated below in Table 8. It should be noted that the original structure here can refer to the original structures in Tables 1 to 4 above. The more the protruding blocks are arranged (which can also be understood as that the larger the area of protruding blocks is), the greater the probability of acoustic reflection is, and the more significant the effect of increasing the Qs and the Qp is. Therefore, it is better to arrange more protruding blocks.

TABLE 8

| | | Number of | Number of | Number of |
|---|---|---|---|---|
| | Original | protruding | protruding | protruding |
| | structure | blocks = 4 | blocks = 8 | blocks = 16 |
| Qs | 2182 | 2438 | 2410 | 2496 |
| Qp | 2381 | 3052 | 3056 | 3113 |

FIG. 6A is a cross-sectional diagram of another bulk acoustic resonance structure and FIG. 6B is a top view diagram of the another bulk acoustic resonance structure according to an embodiment of the present disclosure. The cross-sectional diagram (i.e. FIG. 6A) is a cross-sectional diagram of the bulk acoustic resonance structure (i.e. FIG. 6B) along the B-B cross section direction.

As illustrated in FIGS. 6A and 6B, in some embodiments, the bulk acoustic resonance structure further includes a first electrode lead 113, a first conductive thickening layer 123, a second electrode lead 115 and a second conductive thickening layer 125.

The first electrode lead 113 is connected to the first electrode layer 103 and is located outside an active area.

The first conductive thickening layer 123 is located between the first electrode lead 113 and the piezoelectric layer 104.

The second electrode lead 115 is connected to the second electrode layer and is located outside the active area.

The second conductive thickening layer 125 covers the second electrode lead 115.

Other similar structures of the bulk acoustic resonance structure in the embodiments of the present disclosure can be understood with reference to FIGS. 1A and 1B and would not be repeated here.

As illustrated in FIG. 6B in some embodiments the protruding blocks are not disposed in the area covered by the second electrode lead 115 or the area covered by the second conductive thickening layer 125. Here, the first conductive thickening layer 123 functions to thicken a thickness of the first electrode lead 113. The first conductive thickening layer 123 and the first electrode lead 113 function together as a thickened lead line of the first electrode layer 103, such that the resistance of the thickened lead line can be reduced, thereby reducing the loss.

Connection of devices through the first conductive thickening layer 123 and the second conductive thickening layer 125 can reduce the lateral parasitic capacitance caused by direct connection of the first electrode layer 103 and the second electrode 105 (through first electrode lead 113 and second electrode lead 115).

In some embodiments, when the material(s) of the protruding blocks is(are) the same as a material(s) of the second electrode lead, the protruding blocks may be disposed in an area covered by the second electrode lead 115 or an area covered by the second conductive thickening layer 125. Thus, the protruding blocks which are located below the second electrode lead have the effect of further thickening the second electrode lead.

In some embodiments, the first conductive thickening layer has the same shape as that of the first electrode lead; and/or, the second conductive thickening layer has the same shape as that of the second electrode lead.

Here the shape of the first electrode lead and the shape of the second electrode lead may include, but are not limited to, a strip. The first conductive thickening layer and the second conductive thickening layer can be of any shape that can completely cover the first electrode lead and the second electrode lead respectively, such as a strip.

In some embodiments, a material(s) of the first conductive thickening layer is(are) the same as or different from a material(s) of the first electrode lead; and/or, a material(s) of the second conductive thickening layer is the same as or different from the material(s) of the second electrode lead.

The material(s) of the first conductive thickening layer and the material(s) of the second conductive thickening layer may include aluminum (Al), molybdenum (Mo), ruthenium (Ru), iridium (Ir), platinum (Pt), or the like. The material(s) of the first electrode lead and the material(s) of the second electrode lead may include Al, Mo, Ru, Ir, Pt, or the like.

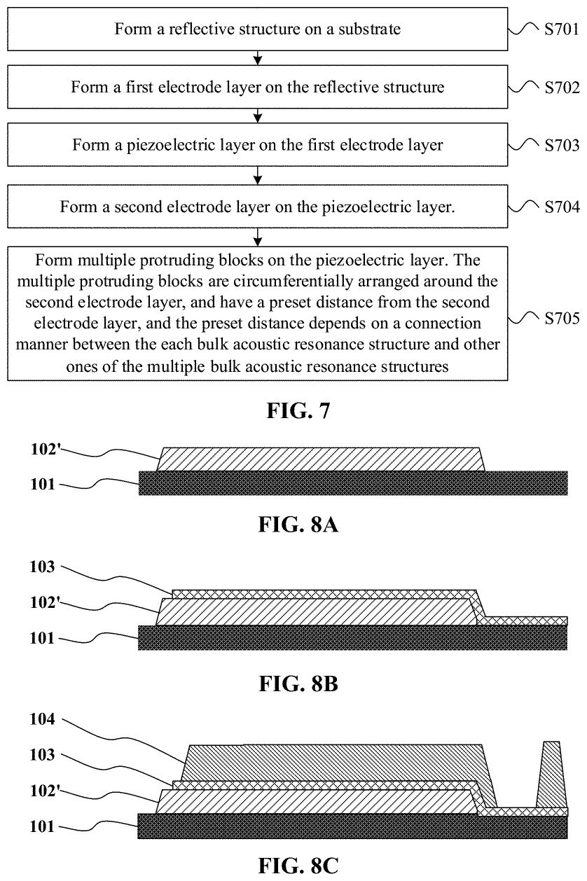

FIG. 7 is a flowchart of implementation of a method for manufacturing a bulk acoustic resonance structure according to an embodiment of the present disclosure. A second aspect of the embodiments of the present disclosure provides a method for manufacturing an acoustic device. The acoustic device includes multiple bulk acoustic resonance structures, and the method of forming each of the multiple bulk acoustic resonance structures includes the following operations.

At block 701, a reflective structure is formed on a substrate.

At block 702, a first electrode layer is formed on the reflective structure.

At block 703, a piezoelectric layer is formed on the first electrode layer.

At block 704, a second electrode layer is formed on the piezoelectric layer.

At block 705, multiple protruding blocks are formed on the piezoelectric layer. Herein the multiple protruding blocks are circumferentially arranged around the second electrode layer. The multiple protruding blocks have a preset distance from the second electrode layer, and the preset distance depends on a connection manner between the each bulk acoustic resonance structure and other ones of the multiple bulk acoustic resonance structures. A material(s) of the multiple protruding blocks may be the same as or different from a material(s) of the second electrode layer. The material(s) of the multiple protruding blocks may include Al, Mo, Ru, Ir, Pt, or the like.

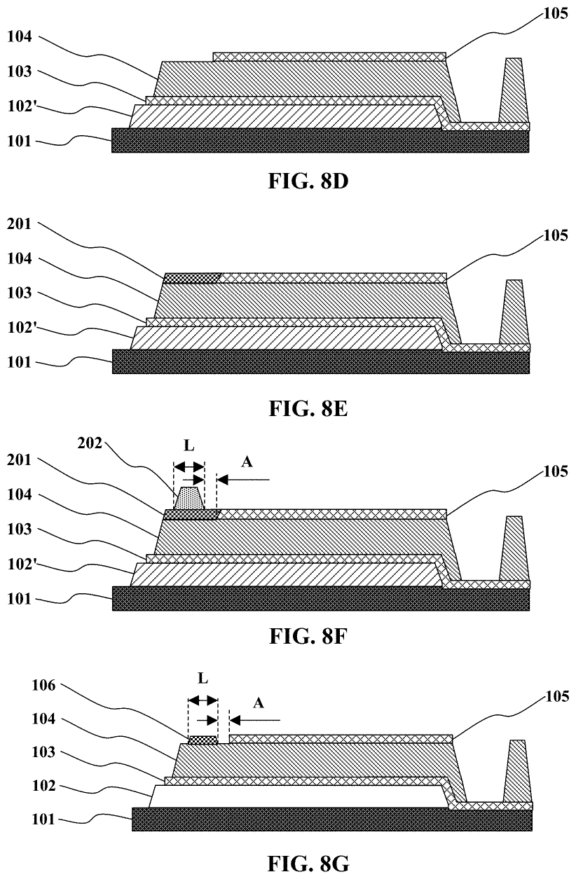

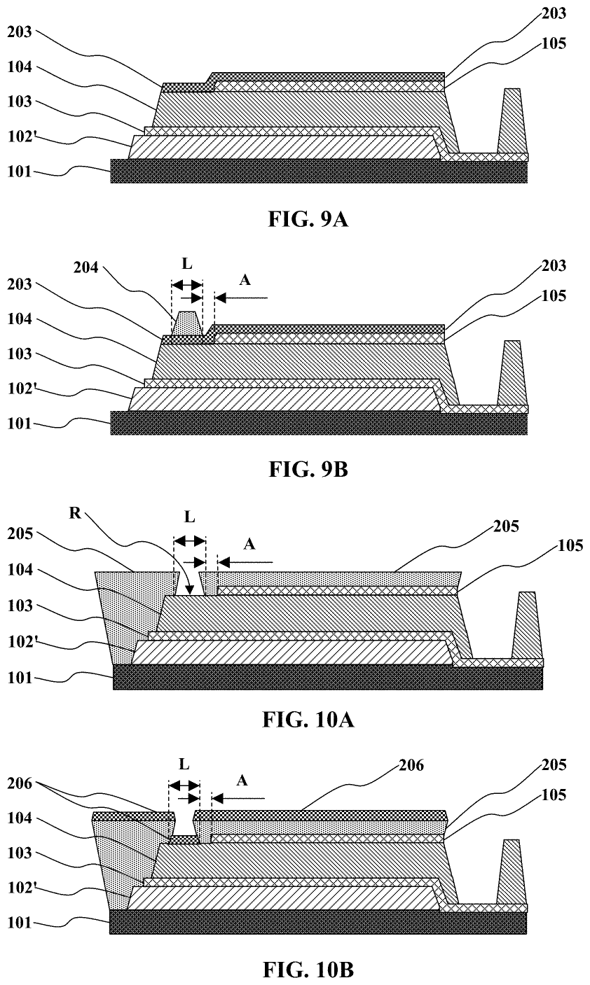

It should be noted that, as illustrated in FIG. 8G, in a case that the reflective structure 102 includes a first cavity formed between a protrusion on the first electrode layer 103 and the surface of the substrate 101, a material(s) at a position of the sacrificial structure 102′ in FIGS. 8A to 8F, in FIGS. 9A and 9B and in FIGS. 10A and 10B should be understood as a sacrificial material (e.g silicon oxide), which would be removed through an etching hole (not illustrated in FIG. 8G) after forming the second electrode layer 105, to obtain a cavity-type reflective structure 102 (as illustrated in FIG. 8G). Description is made here and below by taking the cavity-type reflective structure 102 as an example.

As illustrated in FIG. 8A to 8D, operations of the blocks 701 to 704 are performed. In some implementations, the methods for manufacturing the substrate 101, the reflective structure 102, the first electrode layer 103, the piezoelectric layer 104 and second electrode layer 105 are mature, and would be briefly explained here. Here the method for forming the protruding blocks would be described in detail. The constituent materials of the substrate 101, the sacrificial structure 102′ (e.g. silicon oxide), the first electrode layer 103, the piezoelectric layer 104 and the second electrode layer 105 can be described with reference to the above description of FIGS. 1A and 1B, and would not be described here.

Operation of the block 705 is performed to form the multiple protruding blocks.

In some embodiments, the multiple protruding blocks are formed, which includes the following operations.

As illustrated in FIGS. 8E to 8G, a first material layer 201 covering part of the piezoelectric layer is formed. Herein the first material layer 201 is in contact with the second electrode layer 105. Multiple first mask layers 202 covering parts of the first material layer 201 are formed, where the multiple first mask layers 202 are circumferentially arranged around the second electrode layer 105. Remaining parts of the first material layer not covered by the multiple first mask layers 201 are removed, and a distance A between the piezoelectric layer and each of the parts of the first material layer covered by a respective one of the multiple first mask layers are adjusted to obtain the multiple protruding blocks 106 (referring to FIG. 8G).

It should be noted that the material(s) of the multiple protruding blocks may be different from the material(s) of the second electrode layer. The material(s) of the first mask layer may include, but is not limited to, a photoresist material.

Alternatively, as illustrated in FIGS. 9A to 9B and in FIG. 8G, a second material layer 203 covering part of the piezoelectric layer 104 and the second electrode layer 105 is formed. Multiple second mask layers 204 covering parts of the second material layer 203 are formed, where the multiple second mask layers 204 are circumferentially arranged around the second electrode layer 105 and have the preset distance A from the second electrode layer 105. Remaining parts of the second material not covered by the multiple second mask layers are removed to obtain the multiple protruding blocks 106 (referring to FIG. 8G).

It should be noted that the material(s) of the multiple protruding blocks may be different from the material(s) of the second electrode layer. The material(s) of the second mask layer may include, but is not limited to, a photoresist material.

Alternatively, as illustrated in FIGS. 10A to 10B and in FIG. 8G, a sacrificial layer 205 covering part of the piezoelectric layer 104 and the second electrode layer 105 is formed. Multiple grooves R exposing part of the top surface of the piezoelectric layer 104 in the sacrificial layer 205 are formed, where the multiple grooves R are circumferentially arranged around the second electrode layer 105 and have the preset distance A from the second electrode layer. A third material layer 206 is formed at bottoms of the multiple grooves R and on the top surface of the sacrificial layer 205. The parts of the third material layer 206 on the top surface of the sacrificial layer and the sacrificial layer 205 are removed to reserve the parts of the third material layer at the bottoms of the multiple grooves, so as to obtain the multiple protruding blocks 106 (referring to FIG. 8G).

It should be noted that the material(s) of the multiple protruding blocks may be the same as or different from the material(s) of the second electrode layer. The material(s) of the sacrificial layer may include, but is not limited to, a photoresist material. The material(s) of the sacrificial layer may specifically include, but is not limited to, silicon oxide (SiO₂).

As illustrated in FIGS. 6A and 6B, in some embodiments, the bulk acoustic resonance structure further includes a first electrode lead 113, a first conductive thickening layer 123, a second electrode lead 115 and a second conductive thickening layer 125.

The operation of forming first electrode lead and the piezoelectric layer includes the following operations.

Referring to FIGS. 8B and 6A, both the first electrode layer and the first electrode lead are formed on the reflective structure. Herein the first electrode lead is connected to the first electrode layer and located outside an active area.

Continuing to refer to FIG. 6A, the first conductive thickening layer 123 covering the first electrode lead 113 is formed.

Continuing to refer to FIGS. 8C and 6A, the piezoelectric layer covering the first electrode layer and the first conductive thickening layer is formed.

The operation of forming second electrode layer includes the following operations.

Continuing to refer to FIGS. 8D and 6A, both the second electrode layer 105 and the second electrode lead 115 are formed on the piezoelectric layer 104. Herein the second electrode lead 115 is connected to the second electrode layer 105 and located outside the active area

The method further includes that the second conductive thickening layer 125 covering the second electrode lead 115 is formed.

Other parts not mentioned in the method for manufacturing the bulk acoustic resonance structure in the embodiments of the present disclosure can refer to the description in the aforementioned embodiments of the manufacturing method, which will not be repeated here.

The bulk acoustic resonance structure produced by using the method for manufacturing the bulk acoustic resonance structure provided in the embodiments of the present disclosure is similar to the bulk acoustic resonance structure in the above mentioned embodiments. Technical features not disclosed in detail in the embodiments of the present disclosure are understood with reference to the above mentioned embodiments, and would not be described here.

It should be understood that “an embodiment” or “the embodiment” mentioned throughout the description means that specific features, structures or characteristics related to the embodiments are included in at least one embodiment of the present disclosure. Therefore, “in an embodiment” or “in the embodiment” appearing throughout the description may not necessarily refer to the same embodiments. Furthermore, the specific features, structures or characteristics may be combined in any suitable manner in one or more embodiments. It should be understood that in various embodiments of the present disclosure, sequence numbers of the foregoing processes do not mean execution sequences. The execution sequences of the processes should be determined according to functions and internal logic of the processes, and should not be construed as any limitation on the implementation processes of the embodiments of the present disclosure. The above-mentioned numerals of the embodiments of the present disclosure are only for description, and do not represent the advantages and disadvantages of the embodiments.

The methods disclosed in the several method embodiments of the present disclosure can be arbitrarily combined without conflict to obtain a new method embodiment.

The foregoing description is merely a specific embodiment of the present disclosure, but the scope of protection of the present disclosure is not limited to this. Any change or replacement readily contemplated by those skilled in the art within the technical scope disclosed in the present disclosure shall fall within the scope of protection of the present disclosure. Accordingly, the scope of protection of the present disclosure shall be subject to the scope of protection of the claims.

What is claimed is:

1. An acoustic device comprising a plurality of bulk acoustic resonance structures, wherein each of the plurality of bulk acoustic resonance structures comprises:
a substrate;
a reflective structure, a first electrode layer, a piezoelectric layer and a second electrode layer stacked on the substrate in sequence; and
a plurality of protruding blocks located on the piezoelectric layer and circumferentially arranged around the second electrode layer, wherein the plurality of protruding blocks have a preset distance from the second electrode layer, and the preset distance depends on a connection manner between the each bulk acoustic resonance structure and other ones of the plurality of bulk acoustic resonance structures.

2. The acoustic device of claim 1, wherein in a case that the bulk acoustic resonance structure is connected to a branch of the acoustic device in series, the preset distances is less than or equal to a first distance; or
in a case that the bulk acoustic resonance structure is connected to the branch of the acoustic device in parallel, the preset distance is greater than the first distance.

3. The acoustic device of claim 2, wherein the first distance is greater than or equal to zero and is less than a spacing between an outer contour of the piezoelectric layer and an outer contour of the second electrode layer.

4. The acoustic device of claim 3, wherein the first distance is 4 μm.

5. The acoustic device of claim 1, wherein distances between the plurality of protruding blocks and the second electrode layer are the same or different.

6. The acoustic device of claim 1, wherein each of the plurality of protruding blocks has a size of 0.5 μm to 4 μm in a first direction, a size of 10 μm to 40 μm in a second direction, and a size of 0.1 μm to 1 μm in a third direction,
wherein the first direction is a direction from an edge of the second electrode layer to a middle of the second electrode layer, the second direction is perpendicular to the first direction and parallel to a surface of the substrate, and the third direction is perpendicular to the surface of the substrate.

7. The acoustic device of claim 6, wherein the each of the plurality of protruding blocks has a size of 2 μm in in the first direction, a size of 10 μm in the second direction and a size of 0.5 μm in the third direction.

8. The acoustic device of claim 1, wherein an outer contour of the second electrode layer is of a closed shape comprising a curve and two or more straight lines.

9. The acoustic device of claim 8, wherein the closed shape comprises the curve and the two straight lines of a same length, and the two straight lines form an angle of 0 degree to 180 degrees,
wherein a maximum distance between the curve and an intersection of the two straight lines is L1, each of the two straight lines has a length of L2, and a ratio of L2 to (L1−L2) ranges from 1:0.1 to 1:6.

10. The acoustic device of claim 9, wherein the ratio of L2 to (L1−L2) is 1:3, and the two straight lines form an angle of 45 degrees to 135 degrees.

11. The acoustic device of claim 8, wherein the closed shape comprises the curve, a first straight line, a second straight line and a third straight line, the first straight line is connected to one end of the curve and one end of the third straight line, the second straight line is connected to another end of the curve and another end of the third straight line, the first straight line and the third straight line form an angle of 90 degrees, and the second straight line and the third straight line form an angle of 90 degrees,
wherein a maximum distance between the curve and the third straight line is L3, each of first straight line and the second straight line has a length of L4, and a ratio of (L3−L4) to L4 ranges from 0.36:1 to 4.5:1.

12. The acoustic device of claim 1, wherein the bulk acoustic resonance structure further comprises:
a first electrode lead connected to the first electrode layer and located outside an active area;
a first conductive thickening layer located between the first electrode lead and the piezoelectric layer;
a second electrode lead connected to the second electrode layer and located outside the active area; and
a second conductive thickening layer covering the second electrode lead.

13. The acoustic device of claim 12, wherein the first conductive thickening layer has a same shape as that of the first electrode lead; and/or
the second conductive thickening layer has a same shape as that of the second electrode lead.

14. The acoustic device of claim 12, wherein a material of the first conductive thickening layer is the same as or different from a material of the first electrode lead, and/or,
a material of the second conductive thickening layer is the same as or different from a material of the second electrode lead.

15. A method for manufacturing an acoustic device, wherein the acoustic device comprises a plurality of bulk acoustic resonance structures, and the method comprises: forming each of the plurality of bulk acoustic resonance structures, comprising:
forming a reflective structure on a substrate;
forming a first electrode layer on the reflective structure;
forming a piezoelectric layer on the first electrode layer;
forming a second electrode layer on the piezoelectric layer; and
forming a plurality of protruding blocks on the piezoelectric layer, wherein the plurality of protruding blocks are circumferentially arranged around the second electrode layer, wherein the plurality of protruding blocks have a preset distance from the second electrode layer, and the preset distance depends on a connection manner between the bulk acoustic resonance structure and other ones of the plurality of bulk acoustic resonance structures.

16. The method of claim 15, wherein forming the plurality of protruding blocks comprises:
forming a first material layer covering part of the piezoelectric layer, wherein the first material layer is in contact with the second electrode layer; forming a plurality of first mask layers covering parts of the first material layer, wherein the plurality of first mask layers are circumferentially arranged around the second electrode layer; removing remaining parts of the first material layer not covered by the plurality of first mask layers; and adjusting a distance between the piezoelectric layer and each of the parts of the first material layer covered by a respective one of the plurality of first mask layers, to obtain the plurality of protruding blocks; or
forming a second material layer covering part of the piezoelectric layer and the second electrode layer; forming a plurality of second mask layers covering parts of the second material layer, wherein the plurality of second mask layers are circumferentially arranged around the second electrode layer and have the preset distance from the second electrode layer; and removing remaining parts of the second material not covered by the plurality of second mask layers to obtain the plurality of protruding blocks; or
forming a sacrificial layer covering part of the piezoelectric layer and the second electrode layer; forming a plurality of grooves exposing part of a top surface of the piezoelectric layer in the sacrificial layer, wherein the plurality of grooves are circumferentially arranged around the second electrode layer and have the preset distance from the second electrode layer; forming a third material layer at bottoms of the plurality of grooves and on a top surface of the sacrificial layer; and removing parts of the third material layer on the top surface of the sacrificial layer and the sacrificial layer to reserve remaining parts of the third material layer at the bottoms of the plurality of grooves, so as to obtain the plurality of protruding blocks.

17. The method of claim 15, wherein the bulk acoustic resonance structure further comprises a first electrode lead, a first conductive thickening layer, a second electrode lead, and a second conductive thickening layer,
wherein forming the first electrode lead and forming the piezoelectric layer comprises:
forming both the first electrode layer and the first electrode lead on the reflective structure, wherein the first electrode lead is connected to the first electrode layer and located outside an active area;
forming the first conductive thickening layer covering the first electrode lead;
forming the piezoelectric layer covering the first electrode layer and the first conductive thickening layer;
wherein forming the second electrode layer comprises:
forming both the second electrode layer and the second electrode lead on the piezoelectric layer, wherein the second electrode lead is connected to the second electrode layer and located outside the active area;
wherein the method further comprises:
forming the second conductive thickening layer covering the second electrode lead.
